(19) United States
(12) Patent Application Publication
(10) Pub. No.: US 2008/0199805 A1
(43) Pub. Date: Aug. 21, 2008

(54) PHOTOSENSITIVE COMPOSITIONS EMPLOYING SILICON-CONTAINING ADDITIVES

(75) Inventors: IL'YA RUSHKIN, Acton, MA (US); OGNIAN N. DIMOV, Warwick, RI (US); SANJAY MALIK, Attleboro, MA (US); BINOD B. DE, Attleboro, MA (US)

Correspondence Address: Paul D. Greeley, Esq.;Ohlandt, Greeley, Ruggiero & Perle, L.L.P., 10th Floor, One Landmark Square, Stamford, CT, 06901-2682, US

(73) Assignee: FUJIFILM ELECTRONIC MATERIALS. U.S.A., INC.

(21) Appl. No.: 12/028,512

(22) Filed: Feb. 8, 2008

Related U.S. Application Data
(60) Provisional application No. 60/900,314, filed on Feb. 8, 2007.

(51) Int. Cl. G03F 7/26; G03F 7/004

(52) U.S. Cl. 430/270.1; 430/322; 430/323

(57) ABSTRACT

A photosensitve composition exhibiting high resolution and enhanced, tunable O₂ plasma etch resistance comprising a silicon-containing base polymer, a silicon-containing additive, a photoacid generator and solvent is provided. A method of forming a patterned resist film is also provided.

### RELATED APPLICATIONS

This application claims priority from Provisional Patent Application No. 60/900,314, filed on Feb. 8, 2007.

### FIELD OF THE DISCLOSURE

This disclosure relates to photosensitive compositions with high resolution, wide process latitude and excellent photospeed useful in the manufacture of semiconductor devices, and to the process of using such photosensitive compositions for producing imaged patterns on substrates for the production of such semiconductor devices.

### BACKGROUND OF THE DISCLOSURE

In the semiconductor industry there is a continuing desire to reduce the size of microelectronic devices in order to provide a greater amount of circuitry for a given chip size. This drive to miniaturize microelectronic devices has demanded continual improvements in the lithographic methods used to create the fine patterns of those devices. To meet these demands, imaging wavelengths have decreased from 365 nm to 248 nm to 193 nm and beyond. This, in turn, has placed ever increasing demands on the photoresist materials used for pattern formation.

Advanced photoresist formulations are generally a mixture of at least three components: (1) a developer-insoluble polymer; (2) a photoacid generator (PAG) and; (3) a solvent. Typical lithographic processes involve forming a pattern in a photoresist layer by patternwise exposing the radiation-sensitive photoresist to imaging radiation. Upon exposure to imaging radiation, the PAG generates a strong acid which catalyzes the removal of acid-sensitive blocking groups on the polymer through a process known as chemical amplification. Removal of these acid-sensitive groups serves as a solubility switch, making the newly deblocked polymer developer-soluble. The image is subsequently developed by treating the exposed resist with a developer (typically an aqueous alkaline solution) which selectively removes portions of the resist layer to reveal the desired pattern. A base additive can be added as a diffusion control agent to prevent the photogenerated acid from migrating too far into the unexposed portion of the photoresist layer and lowering resolution. The developed pattern is then transferred to the underlying material by, for example, etching the material in regions where the resist layer has been removed. After pattern transfer is complete, the remaining resist layer is then removed. Many advanced photoresist formulations also contain one or more performance-enhancing additives, such as dissolution inhibitors/promoters and surfactants. The most common types of photoresists are called single layer resists in which the photoresist must perform both the function of imaging and of providing etch resistance.

The resolution capability of lithographic processes is dependent, for example, on the wavelength of the imaging radiation, the quality of the optics in the exposure tool, and the thickness of the photoresist imaging layer. As the thickness of the photoresist imaging layer decreases, the resolution capability increases. Improving resolution by thinning a conventional single layer resist results in an unacceptable decrease in etch protection of the underlying structure or film. To overcome this deficiency of single layer resists, multilayer lithographic systems, such as bilayer systems, have been developed. In bilayer systems, a thin, silicon-containing photoresist imaging layer (IL) is coated onto a thicker planarizing underlayer (UL). Following patternwise exposure and development of the IL, the bilayer system is subjected to an oxidative plasma which converts the silicon-containing species in the IL into SiO₂ or similar oxidized silicon species, thus protecting the underlying UL. In addition, the uncovered UL is oxidized away and the pattern in the resist is transferred into the UL. The patterned UL then acts as a mask for subsequent processes needed to transfer the pattern into the underlying substrate. Examples of bilayer photoresists can be found in U.S. Pat. No. 6,359,078, U.S. Pat. No. 5,985,524, U.S. Pat. No. 6,028,154, U.S. Pat. No. 6,146,793, U.S. Pat. No. 6,165,682, and U.S. Pat. No. 6,916,543 each of which is incorporated by reference in its entirety.

The use of silicon-containing additives in bilayer photoresist compositions has been described in U.S. Pat. No. 6,770,418. A key drawback of these additives is their propensity to outgas silicon-containing fragments upon exposure to deep UV radiation. In addition, they possess a low silicon content (<20 wt %) thereby imparting only a modest increase in etch resistance. Polyhedral oligomeric silsesquioxanes (POSS) are a class of compounds composed of Si—O cage structures. POSS- and other silsesquioxane-based polymers have been shown to exhibit no appreciable outgassing of silicon-containing species upon exposure to deep UV radiation. In addition, the cage-like POSS moieties contain a significant amount of highly oxidized silicon which imparts excellent etch resistance. Silicon containing polymeric additives have been described in U.S. Pat. No. 6,210,856 for use in single layer or bilayer photoresists. Non-polymeric POSS materials bearing acid-sensitive functional groups have also been disclosed for use as photoresist additives in U.S. Pat. Appl. Publication No. 2006/0063103.

The present disclosure serves the need for a non-Si-outgassing bilayer photoresist material with increased oxygen plasma etch resistance for the creation of fine semiconductor patterns.

### SUMMARY OF THE DISCLOSURE

This disclosure describes novel photosensitive compositions, Compositions A), Compositions B) and Compositions C), with high resolution, wide process latitude and excellent photospeed useful in the manufacture of semiconductor devices, and describes the process of using such photosensitive compositions for producing imaged patterns on substrates for the production of such semiconductor devices. The photosensitive compositions of the present disclosure are characterized by the presence of silicon-containing additives in combination with a silicon-containing base polymer. These photosensitive compositions are useful in both single layer and multilayer resist systems. Their use is most preferred in bilayer photoresist systems.

In a first embodiment, the disclosure provides novel photosensitive compositions comprising Composition A) wherein the Composition A) comprises:
a) a polyhedral oligomeric silsesquioxane (POSS) compound selected from compounds of structures (IA)-(IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IA) to (IE) are as follows

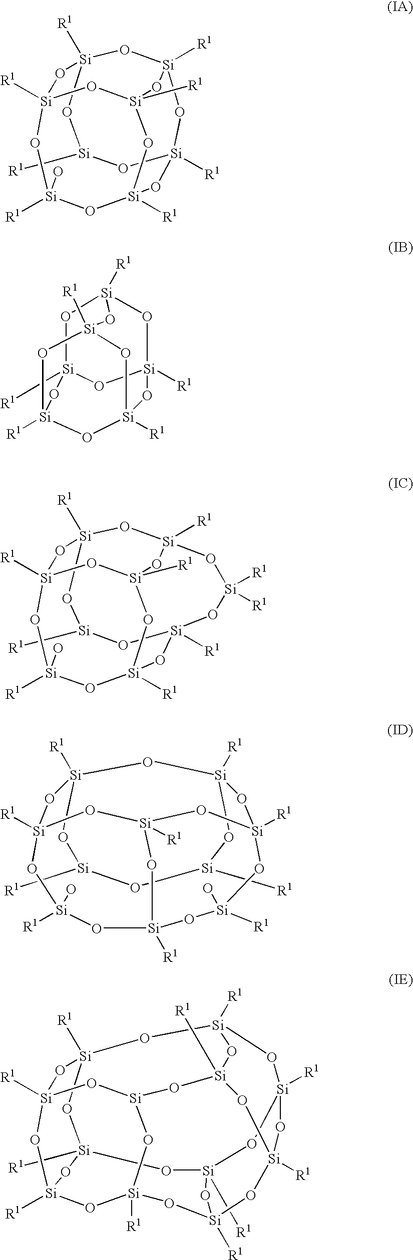

wherein each R¹ is independently a radical of formula (A)

-(J¹)_{c}-(L¹)_{d}-R² (A)

wherein c is an integer from zero to 3;
d is zero or 1;
J¹ is a substituted or unsubstituted C₁-C₁₂ linear, branched or cyclic alkylene group or a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group;
R² is selected from the group consisting of
1) —OR⁵ wherein R⁵ is either a hydrogen atom or a substituted or unsubstituted C₁-C₁₂ linear, branched or cyclic alkyl group; and
2) a cyclic anhydride group of structure (IIA) or a lactone group of structure (IIB):

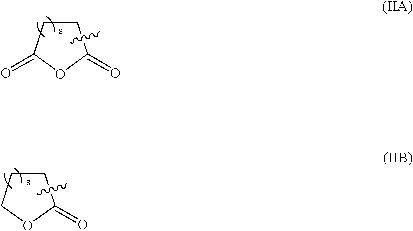

preferably structures (IIA¹) and (IIB¹)

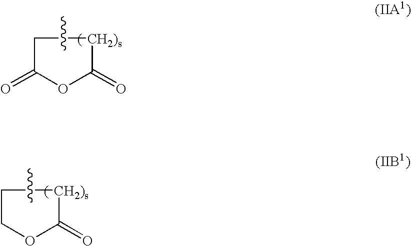

wherein s is an integer from 0 to 3 and structures (IIA), (IIA¹), (IIB) and (IIB¹) may be bonded to L¹ in one or more places.

In a second embodiment, the disclosure provides novel photosensitive compositions comprising Composition B) wherein Composition B) comprises:
a) a polyhedral oligomeric silsesquioxane (POSS) compound selected from compounds of structures (IF) and (IG);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IF) and (IG) are as follows

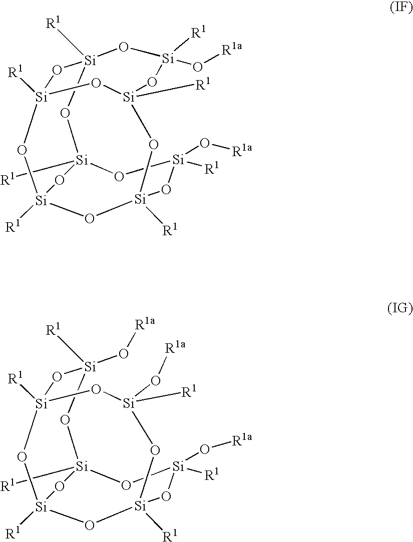

wherein each R¹ is independently a radical of formula (A)

-(J¹)_{c}-(L¹)_{d}-R² (A)

wherein c is an integer from zero to 3;
d is zero or 1;
J¹ is a substituted or unsubstituted C₁-C₁₂ linear, branched or cyclic alkylene group or a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group;
R² is selected from the group consisting of
1) a hydrogen atom;
2) —OR⁵ wherein R⁵ is either a hydrogen atom or a substituted or unsubstituted C₁-C₁₂ linear, branched or cyclic alkyl group; and
3) a cyclic anhydride group of structure (IIA) or a lactone group of structure (IIB):

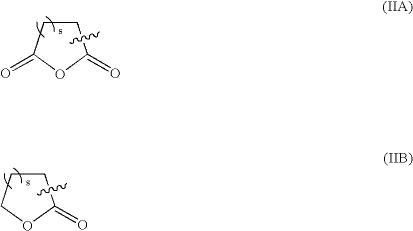

preferably structures (IIA¹) and (IIB¹)

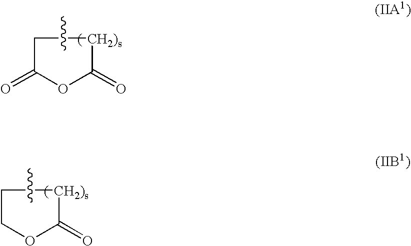

wherein s is an integer from 0 to 3 and structures (IIA), (IIA¹), (IIB) and (IIB¹) may be bonded to L¹ in one or more places;
   each R^{1a} is independently a radical of formula (B)

—(SiR⁶R⁷)-(G)ₑ-R⁸ (B)

wherein R⁶ and R⁷ are each, independently, a substituted or unsubstituted C₁-C₁₂ linear, branched or cyclic alkyl or aryl group;
G is a substituted or unsubstituted C₁-C₁₂ linear, branched, or cyclic alkylene or arylene group;
e is zero or 1;
and R⁸ is selected from the group consisting of
1) a hydrogen atom;
2) —OR⁹ wherein R⁹ is either a hydrogen atom or a substituted or unsubstituted C₁-C₁₂ linear, branched or cyclic alkyl group; and
3) a cyclic anhydride group of structure (IIIA) or a lactone group of structure (IIIB):

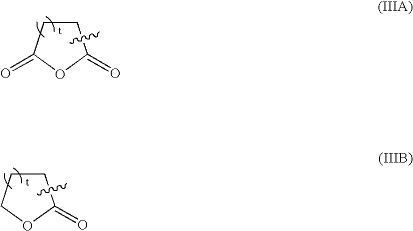

preferably structures (IIIA¹) and (IIIB¹)

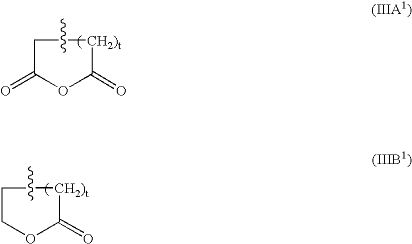

wherein t is an integer from 0 to 3 and structures (IIIA), (IIIA¹), (IIIB) and (IIIB¹) may be bonded to G in one or more places.

In a third embodiment, the disclosure provides novel photosensitive compositions comprising Composition C) wherein the Composition C) comprises:
a) a polyhedral oligomeric silsesquioxane (POSS) compound selected from compounds of structures (IA), (IB), (ID), and (IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IA), (IB), (ID), and (IE) are as follows:

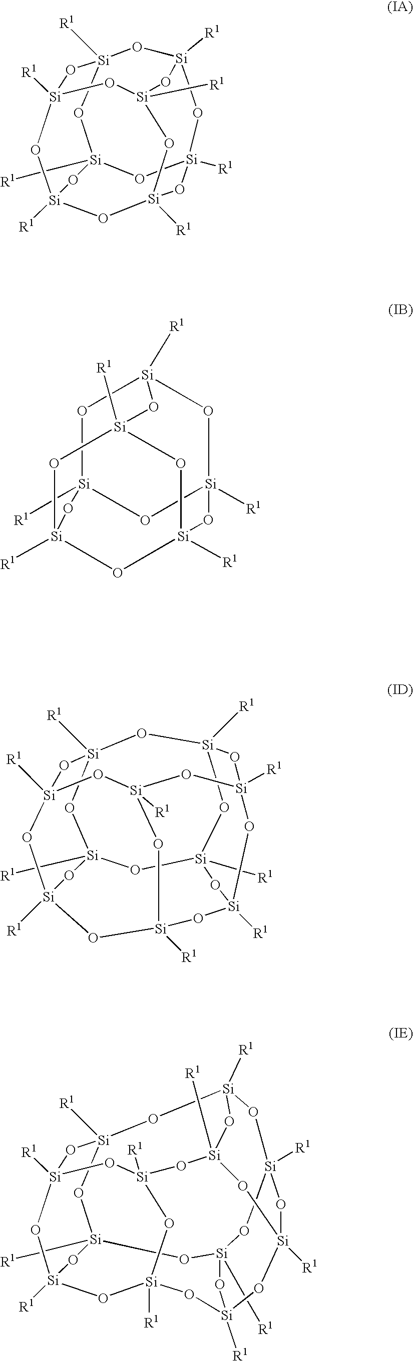

wherein each R¹ is independently a radical of formula (A)

-(J¹)_{c}-(L¹)_{d}-R² (A)

wherein c is an integer from zero to 3;
d is zero;
J¹ is a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group; and
R² is a hydrogen atom.

The photosensitive compositions of the present disclosure provide sub-200 nm resolution, good imaged profiles, high etch resistance, and no unwanted side slopes when used with attenuated phase shift masks.

In addition, a process for the production of relief structures on a substrate for both single layer resist and bi-layer resist systems is being disclosed.

### DETAILED DESCRIPTION OF THE DISCLOSURE

This disclosure provides novel photosensitive compositions with high resolution, wide process latitude and excellent photospeed useful in the manufacture of semiconductor devices, and to the process of using such photosensitive compositions for producing imaged patterns on substrates for the production of such semiconductor devices. The photosensitive compositions of the present disclosure are characterized by the presence of silicon-containing additives in combination with a silicon-containing base polymer. These photosensitive compositions are useful in both single layer and multilayer resist systems. Their use is most preferred in bilayer photoresist systems.

### DEFINITIONS

Unless otherwise noted all parts and percentages are given on a by weight basis (wt %).

The term “developer insoluble” as used in this disclosure refers to a polymeric film coated on a substrate that loses less than 10% of its pre-develop film thickness when treated for a period of 60 seconds with a solution of 0.262 N aqueous tetramethylammonium hydroxide solution under typical conditions found in the art. The terms “developer insoluble”, “developer-insoluble”, “poorly alkali soluble or alkali insoluble” or “alkali insoluble” are interchangeable.

The term “developer soluble” as used in this disclosure refers to a polymeric film coated on a substrate that completely dissolves when treated for a period of 60 seconds with a solution of 0.262 N aqueous tetramethylammonium hydroxide solution under typical conditions found in the art. The term “exhibiting appreciable solubility”, “developer-soluble” and “alkali soluble” are interchangeable.

In a first embodiment, the disclosure provides novel photosensitive compositions comprising Composition A) wherein Composition A comprises:
a) a polyhedral oligomeric silsesquioxane (POSS) compound selected from compounds of structures (IA)-(IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IA) to (IE) are as follows

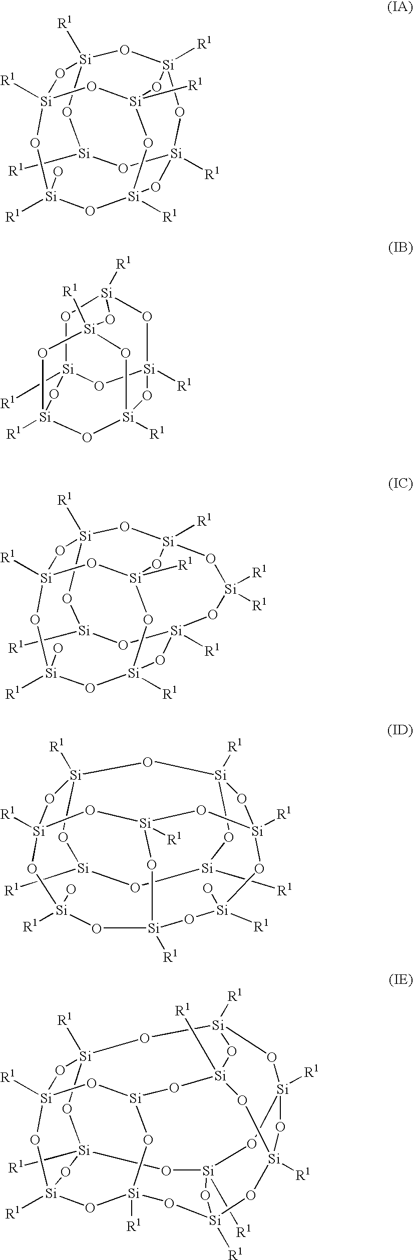

wherein each R¹ is independently a radical of formula (A)

-(J¹)_{c}-(L¹)_{d}-R² (A)

wherein c is an integer from zero to 3;
d is zero or 1;
J¹ is a substituted or unsubstituted C₁-C₁₂ linear, branched or cyclic alkylene group or a —(OSIR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group;
R² is selected from the group consisting of
1) —OR⁵ wherein R⁵ is either a hydrogen atom or a substituted or unsubstituted C₁-C₁₂ linear, branched or cyclic alkyl group; and
2) a cyclic anhydride group of structure (IIA) or a lactone group of structure (IIB):
   (IIA) (IIB)

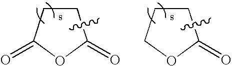

preferably structures (IIA¹) and (IIB¹)

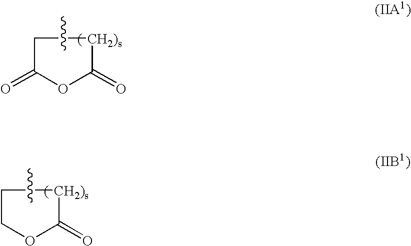

wherein s is an integer from 0 to 3 and structures (IIA), (IIA¹), (IIB) and (IIB¹) may be bonded to L¹ in one or more places.

In a second embodiment, the disclosure provides novel photosensitive compositions comprising Composition B) wherein Composition B) comprises:
a) a polyhedral oligomeric silsesquioxane (POSS) compound selected from compounds of structures (IF) and (IG);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IF) and (IG) are as follows

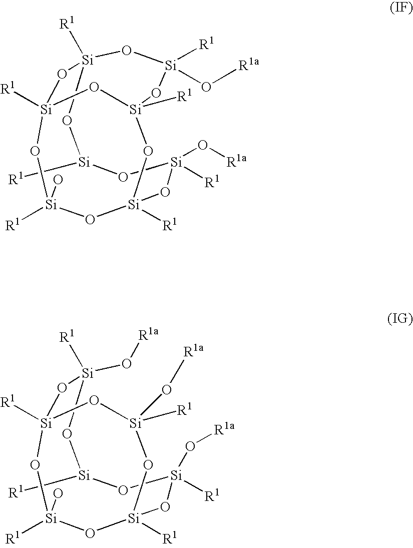

wherein each R¹ is independently a radical of formula (A)

-(J¹)_{c}-(L¹)_{d}-R² (A)

wherein c is an integer from zero to 3;
d is zero or 1;
J¹ is a substituted or unsubstituted C₁-C₁₂ linear, branched or cyclic alkylene group or a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group;
R² is selected from the group consisting of
1) a hydrogen atom;
2) —OR⁵ wherein R⁵ is either a hydrogen atom or a substituted or unsubstituted C₁-C₁₂ linear, branched or cyclic alkyl group; and
3) a cyclic anhydride group of structure (IIA) or a lactone group of structure (IIB):
   (IIA) (IIB)

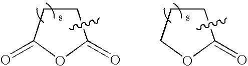

preferably structures (IIA¹) and (IIB¹)

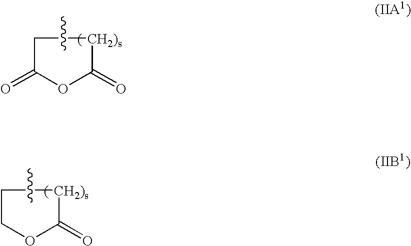

wherein s is an integer from 0 to 3 and structures (IIA), (IIA¹), (IIB) and (IIB¹) may be bonded to L¹ in one or more places;
   each R^{1a} is independently a radical of formula (B)

—(SiR⁶R⁷)-(G)ₑ-R⁸ (B)

wherein R⁶ and R⁷ are each, independently, a substituted or unsubstituted C₁-C₁₂ linear, branched or cyclic alkyl or aryl group;
G is a substituted or unsubstituted C₁-C₁₂ linear, branched, or cyclic alkylene or arylene group;
e is zero or 1;
and R⁸ is selected from the group consisting of
1) a hydrogen atom;
2) —OR⁹ wherein R⁹ is either a hydrogen atom or a substituted or unsubstituted C₁-C₁₂ linear, branched or cyclic alkyl group; and
3) a cyclic anhydride group of structure (IIIA) or a lactone group of structure (IIIB):

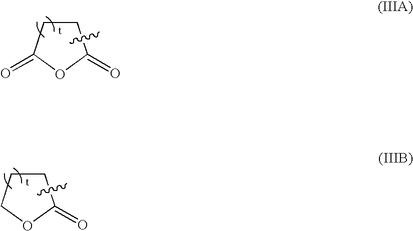

preferably structures (IIIA¹) and (IIIB¹)

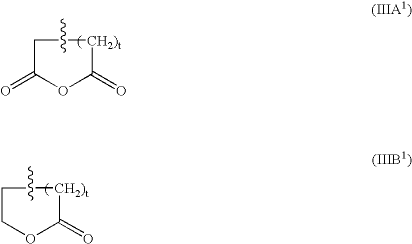

wherein t is an integer from 0 to 3 and structures (IIIA), (IIIA¹), (IIIB) and (IIIB¹) may be bonded to G in one or more places.

In a third embodiment, the disclosure provides novel photosensitive compositions comprising Composition C) wherein Composition C) comprises:
a) a polyhedral oligomeric silsesquioxane (POSS) compound selected from compounds of structures (IA), (IB), (ID), and (IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IA), (IB), (ID), and (IE) are as follows

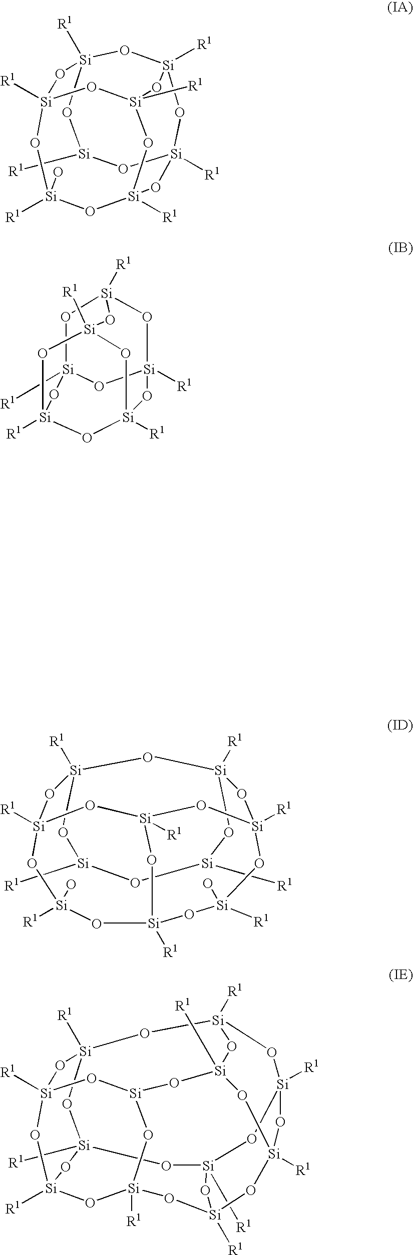

wherein each R¹ is independently a radical of formula (A)

-(J¹)_{c}-(L¹)_{d}-R² (A)

wherein c is an integer from zero to 3;
d is zero;
J¹ is a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group; and
R² is a hydrogen atom.

When J¹ is a substituted or unsubstituted C₁-C₁₂ linear, branched or cyclic alkylene group as is appropriate for the individual embodiments, suitable examples include, but are not limited to, methylene, ethylene, propylene, isopropylidene, n-butylene, cyclobutylene, pentylene, iso-pentylene, neo-pentylene, cyclopentylene, hexylene, cyclohexylene, heptylene, cycloheptylene, octylene, decylene, dodecylene, bicyclo[2.2.1]heptylene, and tetracyclo[4.4.1^{2,5}.1^{7,10}.0]dodecylene. When J¹ is a silyloxy group [—(OSiR³R⁴)—] as is appropriate for the individual embodiments, suitable examples of R³ and R⁴ include, but are not limited to, methyl, ethyl, propyl, n-butyl, tert-butyl, cyclobutyl, pentyl, iso-pentyl, neo-pentyl, cyclopentyl, hexyl, cyclohexyl, heptyl, cyclohexylmethyl, cycloheptyl, 2-cyclohexylethyl, octyl, decyl, dodecyl, bicyclo[2.2.1]heptyl, and phenyl.

Suitable examples of L¹ include, but are not limited to, methylene, ethylene, propylene, isopropylidene, n-butylene, cyclobutylene, pentylene, iso-pentylene, neo-pentylene, cyclopentylene, hexylene, cyclohexylene, heptylene, cycloheptylene, octylene, decylene, dodecylene, bicyclo[2.2.1]heptylene, tetracyclo[4.4.1^{2,5}.1^{7,10}.0]dodecylene, phenylene, biphenylene, and naphthalene.

Suitable examples of R⁵ include, but are not limited to, a hydrogen atom, methyl, ethyl, n-propyl, isopropyl, n-butyl, sec-butyl, tert-butyl, cyclobutyl, pentyl, iso-pentyl, neo-pentyl, cyclopentyl, hexyl, cyclohexyl, heptyl, cyclohexylmethyl, cycloheptyl, 2-cyclohexylethyl, octyl, decyl, and dodecyl.

As is appropriate for the individual embodiments, suitable examples of R² include, but are not limited to, a hydrogen atom, hydroxy, methoxy, ethoxy, n-propoxy, isopropoxy, n-butoxy, sec-butoxy, tert-butoxy, cyclobutoxy, pentoxy, iso-pentoxy, neo-pentoxy, cyclopentoxy, hexyloxy, cyclohexyloxy, heptyloxy, cyclohexylmethoxy, cycloheptyloxy, 2-cyclohexylethoxy, octyloxy, decyloxy, and dodecyloxy. Additional suitable examples of R² include, but are not limited to, 5- and 6-membered anhydrides and lactones such as 2,5-dioxotetrahydrofuran-3-yl and 2-oxotetrahydrofuran-3-yl.

As is appropriate for the individual embodiments, suitable examples of R¹ include, but are not limited to, a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, and R¹-a to R¹-g as shown below:

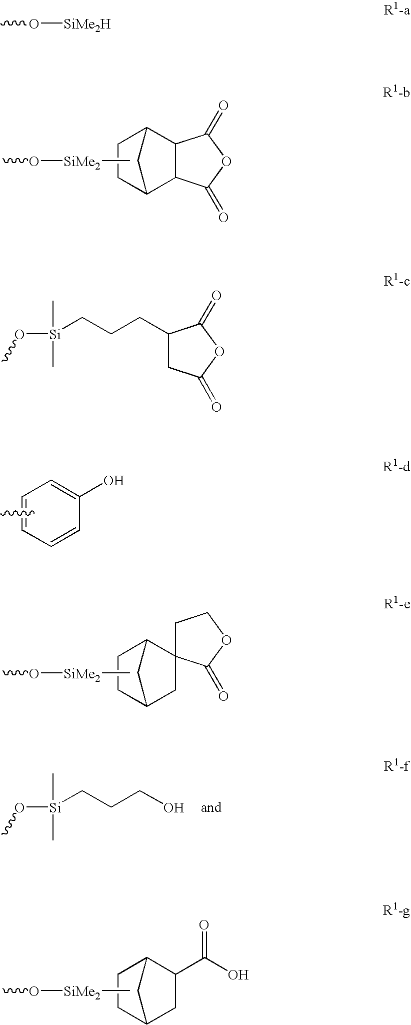

Suitable examples of R⁵ and R⁷ include, but are not limited to, methyl, ethyl, propyl, n-butyl, tert-butyl, cyclobutyl, pentyl, iso-pentyl, neo-pentyl, cyclopentyl, hexyl, cyclohexyl, heptyl, cyclohexylmethyl, cycloheptyl, 2-cyclohexylethyl, octyl, decyl, dodecyl, bicyclo[2.2.1]heptyl, and phenyl.

Suitable examples of G include, but are not limited to, methylene, ethylene, propylene, isopropylidene, n-butylene, cyclobutylene, pentylene, iso-pentylene, neo-pentylene, cyclopentylene, hexylene, cyclohexylene, heptylene, cycloheptylene, octylene, decylene, dodecylene, bicyclo[2.2.1]heptylene, and tetracyclo[4.4.1^{2,5}.1^{7,1.0}]dodecylene, phenylene, biphenylene, and naphthalene.

Suitable examples of R⁹ include, but are not limited to, a hydrogen atom, methyl, ethyl, n-propyl, isopropyl, n-butyl, sec-butyl, tert-butyl, cyclobutyl, pentyl, iso-pentyl, neo-pentyl, cyclopentyl, hexyl, cyclohexyl, heptyl, cyclohexylmethyl, cycloheptyl, 2-cyclohexylethyl, octyl, decyl, and dodecyl.

Suitable examples of R⁸ include, but are not limited to, a hydrogen atom, hydroxy, methoxy, ethoxy, n-propoxy, isopropoxy, n-butoxy, sec-butoxy, tert-butoxy, cyclobutoxy, pentoxy, iso-pentoxy, neo-pentoxy, cyclopentoxy, hexyloxy, cyclohexyloxy, heptyloxy, cyclohexylmethoxy, cycloheptyloxy, 2-cyclohexylethoxy, octyloxy, decyloxy, and dodecyloxy. Additional suitable examples of R⁸ include, but are not limited to, 5- and 6-membered anhydrides and lactones such as 2,5-dioxotetrahydrofuran-3-yl and 2-oxotetrahydrofuran-3-yl.

Suitable examples of R^{1a} include, but are not limited to, Structures R^{1a}-a to R^{1a}-h shown below:

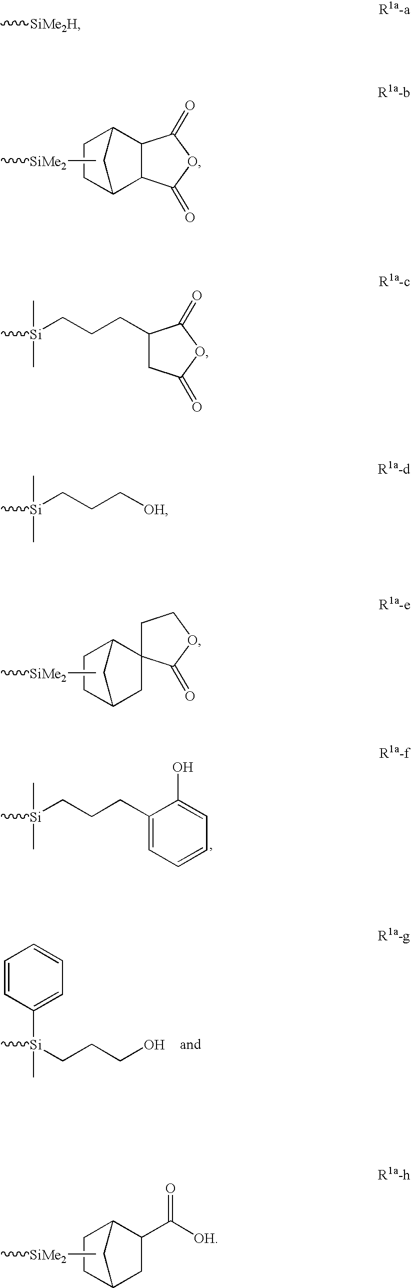

Suitable examples of POSS compounds useful in the present disclosure include, but are not limited, to Structure (IA) wherein each R¹ within the Structure is the same and is a hydrogen atom, hydroxycyclohexyl, dihydroxycyclohexyl, hydroxybicyclo[2.2.1]heptyl, R¹-a, R¹-b, R¹-c, R¹-d, R¹-e or R¹-f, Structure (IB) wherein each R¹ within the Structure is the same and is a hydrogen atom, hydroxycyclohexyl, dihydroxycyclohexyl, hydroxybicyclo[2.2.1]heptyl, R¹-a, R¹-b, R¹-c, R¹-d, R¹-e or R¹-f, Structure (IC) wherein each R¹ within the Structure is the same and is a hydroxycyclohexyl, dihydroxycyclohexyl, hydroxybicyclo[2.2.1]heptyl, R¹-b, R¹-c, R¹-d, R¹-e or R¹-f, Structure (ID) wherein each R¹ within the Structure is the same and is a hydrogen atom, hydroxycyclohexyl, dihydroxycyclohexyl, hydroxybicyclo[2.2.1]heptyl, R¹-a, R¹-b, R¹-c, R¹-d, R¹-e or R¹-f, Structure (IE) wherein each R¹ within the Structure is the same and is a hydrogen atom, hydroxycyclohexyl, dihydroxycyclohexyl, hydroxybicyclo[2.2.1]heptyl, R¹-a, R¹-b, R¹-c, R¹-d, R¹-e or R¹-f, Structure (IF) wherein each R^{1a} is a R^{1a}-a and each R¹ within the Structure is the same and is a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, R¹-a, R¹-b, R¹-c, R¹-d, R¹-e, R¹-f or R¹-g, Structure (IF) wherein each R^{1a} is R^{1a}-d and each R¹ within the Structure is the same and is a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, R¹-a, R¹-b, R¹-c, R¹-d, R¹-e, R¹-f or R¹-g, Structure (IF) wherein each R¹ is methyl and each R^{1a} within the Structure is the same and is R^{1a}-b, R^{1a}-c, R^{1a}-e, R^{1a}-f, R^{1a}-g or R^{1a}-h, Structure (IF) wherein each R¹ is ethyl and each R^{1a} within the Structure is the same and is R^{1a}-b, R^{1a}-c, R^{1a}-e, R^{1a}-f, R^{1a}-g or R^{1a}-h, Structure (IF) wherein each R¹ is cyclohexyl and each R^{1a} within the Structure is the same and is R^{1a}-b, R^{1a}-c, R^{1a}-e, R^{1a}-f, R^{1a}-g or R^{1a}-h, Structure (IG) wherein each R^{1a} is a R^{1a}-a and each R¹ within the Structure is the same and is a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, R¹-a, R¹-b, R¹-c, R¹-d, R¹-e, R¹-f or R¹-g, Structure (IG) wherein each R^{1a} is R^{1a}-d and each R¹ within the Structure is the same and is a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, R¹-a, R¹-b, R¹-c, R¹-d, R¹-e, R¹-f or R¹-g, Structure IG wherein each R¹ is methyl and each R^{1a} within the Structure is the same and is R^{1a}-b, R^{1a}-c, R^{1a}-e, R^{1a}-f, R^{1a}-g or R^{1a}-h, Structure (IG) wherein each R¹ is ethyl and each R^{1a} within the Structure is the same and is R^{1a}-b, R^{1a}-c, R^{1a}-e, R^{1a}-f, R^{1a}-g or R^{1a}-h, and Structure IG wherein each R¹ is cyclohexyl and each R^{1a} within the Structure is the same and is R^{1a}-b, R^{1a}-c, R^{1a}-e, R^{1a}-f R^{1a}-g or R^{1a}-h.

POSS compounds are available commercially from Hybrid Plastics, Inc. (Hattiesburg, Miss.), Mayaterials Inc. (Ann Arbor, Mich.) and Aldrich Chemical Company (Milwaukee, Wis.). The synthesis of various POSS nanostructures can be found in U.S. Pat. No. 5,047,492, U.S. Pat. No. 5,484,867, U.S. Pat. No. 5,939,576, U.S. Pat. No. 5,942,638, U.S. Pat. No. 6,100,417, U.S. Pat. No. 6,660,823, U.S. Pat. No. 6,770,724, U.S. Pat. No. 6,911,518, U.S. Pat. No. 6,927,270, and U.S. Pat. No. 6,972,312 each of which is incorporated by reference in its entirety.

The POSS compound content of the photosensitive composition is from about 0.05 wt % to about 11 wt % of the total solids content. The preferred range is from about 4 wt % to about 10 wt % and the more preferred range is from about 5 wt % to about 9 wt %. The amount of POSS compound used will depend on the nature of the polymer and the other components in the photosensitive composition.

The silicon-containing polymer useful in the disclosure is a material with a molecular weight of from about 1000 to about 100,000 amu. This material is preferably a poorly alkali soluble or alkali insoluble silicon-containing polymer comprising one or more blocked (masked) alkali solubilizing group (acid sensitive group). The functionality blocking the alkali solubilizing group is acid sensitive. The presence of an acid catalyzes the deblocking of the alkali solubilizing group and renders the polymer alkali soluble. Suitable alkali solubilizing groups include, but are not limited to, carboxylic acids, sulfonic acid, phenols, acidic alcohols, hydroxyimides, hydroxymethylimides, and silanols. Suitable alkali solubilizing groups are further described in US Published Patent Appl. 2006/0110677. Monomeric units containing blocked alkali solubilizing groups may or may not contain silicon. Examples of monomeric units containing alkali soluble monomeric units after deblocking include, but are not limited to,

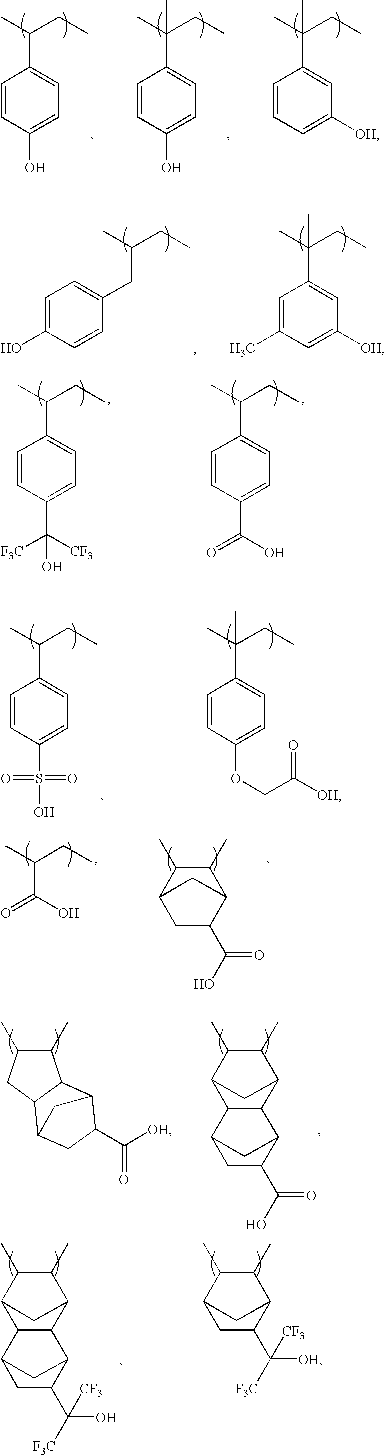

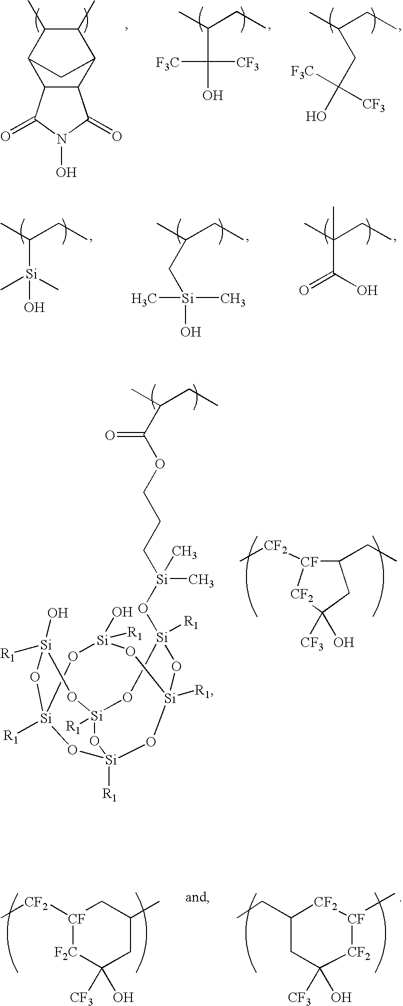

Any number of acid-sensitive protecting groups, known to those skilled in the art, may be employed. Preferred acid-sensitive protecting groups include tertiary alkyl groups, α-alkoxy alkyl groups, arylisopropyl and alicyclic substituted isopropyl groups. Specific acid-sensitive protecting groups include, but are not limited to, t-butyl, 1,1-dimethylpropyl, 1-methyl-1-cyclohexyl, 2-isopropyl-2-adamantyl, tetrahydropyran-2-yl, methoxymethyl, 1-ethoxyethyl and the like. Examples of suitable blocked alkali solubilizing groups include, but are not limited to, tertiary alkyl esters such as t-butyl esters, a alkoxy esters, a alkoxyalkyl aromatic ethers, t-butoxyphenyl, t-butoxyimido, t-butoxycarbonyloxy, and t-butoxymethylimido. Examples of blocked alkali solubilizing groups can be found in U.S. Pat. Nos. 5,468,589, 4,491,628, 5,679,495, 6,379,861, 6,329,125, 6,440,636, 6,830,867, 6,136,501 and 5,206,317, which are incorporated herein by reference.

Examples of suitable monomers containing blocked alkali solubilizing groups include, but are not limited to, t-butyl methacrylate, t-butyl acrylate, and monomers represented by the structures below:

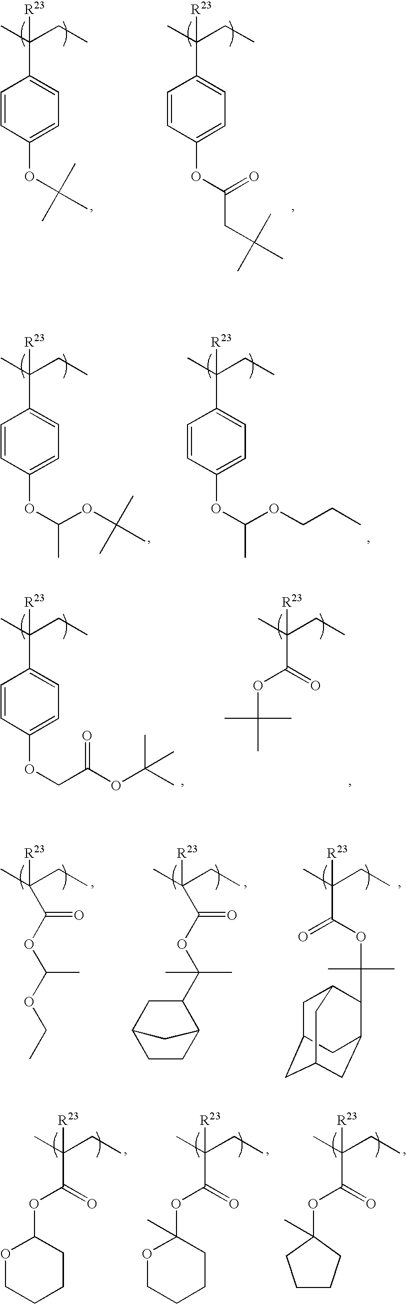

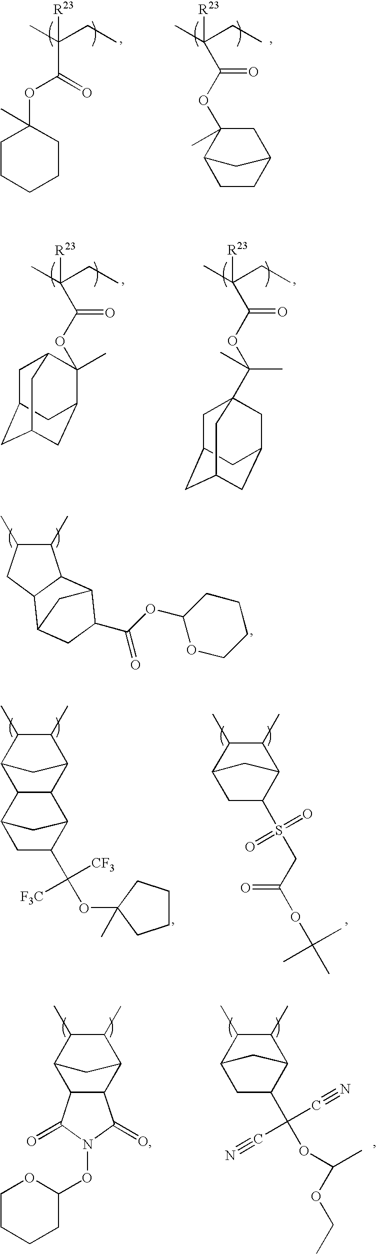

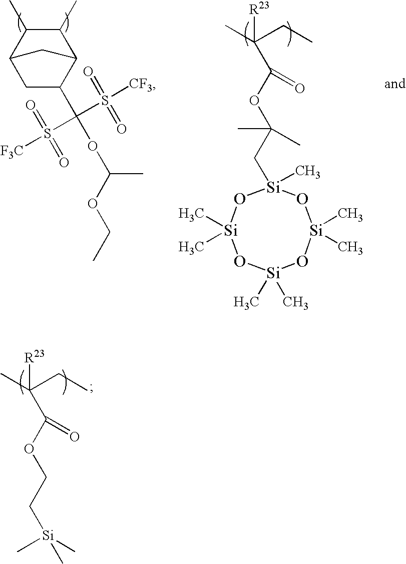

wherein R³ is independently a hydrogen atom, a C₁-C₃ alkyl group, or a C₁-C₃ perfluorinated alkyl group. Examples of preferred R²³ groups include, but are not limited to, hydrogen, methyl or trifluoromethyl.

The silicon-containing polymer further comprises one or more monomeric units comprising one or more silicon moieties. Monomeric units containing one or more silicon moieties may or may not have blocked alkali solubilizing groups. Examples of suitable monomers containing a least one silicon moiety include, but are not limited to, structures VI-IX.

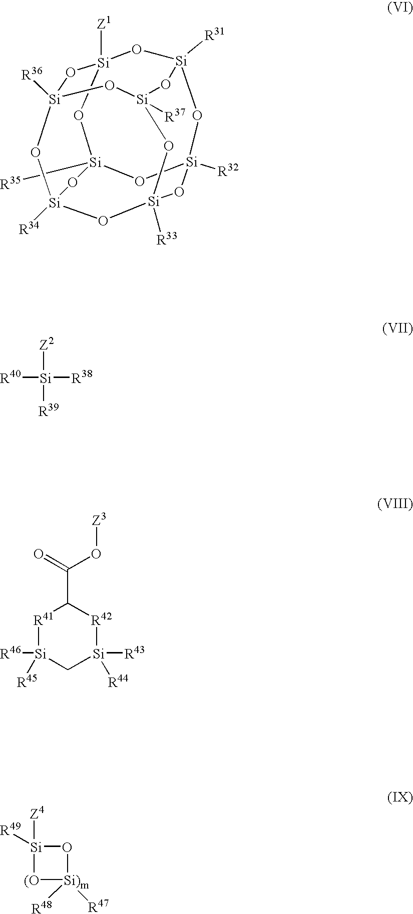

wherein Z¹, Z², Z³, and Z⁴ are each independently a P-Q group, wherein P is a polymerizable group, preferably a moiety containing an ethylenically unsaturated polymerizable group and Q is a single bond or a divalent bridging group. This divalent bridging group may include, but is not limited to, divalent heteroatoms, a divalent acetal, ketal, carbonate group or carboxylic acid ester, a C₁-C₁₂ linear, branched, cyclic or polycyclic alkylene group, a dialkyl siloxyl or a C₆-C₁₄ arylene group. Examples of P groups include, but are not limited to, linear or cyclic alkenes, C₁-C₆ linear vinyl ethers, C₂-C₈ linear or cyclic alkyl acrylic esters, styrene and hydroxyl styrene. Examples of preferred polymerizable groups include, but are not limited to, vinyl, allyl, 1-butenyl, 1-vinyloxyethyl, 2-ethyl acryloyl, 2-propylacryloyl or 2-cyclohexyl acryloyl. Examples of divalent bridging groups include, but are not limited to, methylene, ethylene, propylene, butylene, cyclopentylene, cyclohexylene, bicyclo[2.2.1]heptylene, tetracyclo[4.4.1^{2,5}.1^{7,10}.0]dodecylene, —OC(CH₃)OCH₂—, —CH₂OC(CH₃)₂OC₂H₄—, —C(O)OC(O)CH₂—, —C(O)OC2H4-, —O—, dimethyl siloxyl, phenylene, biphenylene, and naphthalene.

R³¹, R³², R³³, R³⁴, R³⁵, R³⁶ and R³⁷ are each the same and selected from the group consisting of
(1) a linear, branched or cyclic alkyl or a substituted or unsubstituted alicyclic group, having 1 to 20 carbon atoms;
(2) a linear, branched or cyclic fluoroalkyl or fluorine substituted alicyclic group having 1 to 20 carbon atoms; and
(3) a polar group, selected from
   (a) —(CH₂)ₙ—OR⁵⁰,
      where n is an integer of from about 2 to about 10 and R⁵⁰ is a hydrogen atom, a linear, branched or cyclic alkyl or alicyclic group having 1 to 20 carbon atoms, or an α-alkoxy alkyl group;
   (b) —(CH₂)ₒ—(C═O)—OR⁵¹,
      where o is an integer of from about 2 to about 10 and R⁵¹ is a hydrogen atom, a linear, branched or cyclic alkyl or alicyclic group having 1 to 20 carbon atoms, or an acid sensitive protecting group;
   (c) —(CH₂)ₚ—C(CF₃)R⁵²—OR⁵³,
      where p is an integer of from about 2 to about 10 and R⁵² is a hydrogen atom, fluoromethyl, difluoromethyl or trifluoromethyl and R⁵³ is a hydrogen atom or a linear, branched or cyclic alkyl or alicyclic group having 1 to 20 carbon atoms; and
   (d) —(CH₂)ᵣ—O—(C═O)R⁵⁴,
      where r is an integer of from about 2 to about 10 and R⁵⁴ is a linear, branched or cyclic alkyl or alicyclic group having 1 to 20 carbon atoms;

Examples of R⁵⁰ include, but are not limited to, a hydrogen atom, methyl, ethyl, propyl, isopropyl, n-butyl, sec-butyl, tert-butyl, cyclohexyl, cyclopentyl, octyl, cyclooctyl, cyclononyl, cyclodecyl, norbornyl, isobornyl, adamantyl, adamantylmethylene, tricyclo[5,2,1,0^{2.6}]decanemethylene, tetracyclo[4,4,0,1^{2,5},^{17,10}]dodecyl, methoxymethyl, ethoxymethyl, propoxymethyl, isopropoxymethyl, tert-butoxymethyl, 1-methoxyethyl, 1-ethoxyethyl, 1-ethoxypropyl, 1-methoxybutyl, 1-ethoxybutyl, 1-propoxybutyl, 2-methoxy-2-propyl, 2-ethoxy-2-propyl, 1-cyclopentoxyethyl, 1-cyclohexoxyethyl, tetrahydrofuran-2-yl, 2-methyltetrahydrofuran-2-yl, tetrahydropyran-2-yl or 2-methyltetrahydropyran-2-yl groups.

Examples of R⁵¹ include, but are not limited to, a hydrogen atom, methyl, ethyl, propyl, isopropyl, n-butyl, sec-butyl, tert-butyl, cyclohexyl, cyclopentyl, octyl, cyclooctyl, cyclononyl, cyclodecyl, norbornyl, isobornyl, adamantyl, adamantylmethylene, tricyclo[5,2,1,0^{2.6}]decanemethylene, tetracyclo[4,4,0,1^{2,5},1^{17,10}]dodecyl, 1,1-dimethylpropyl, 1-methyl-1-ethylpropyl, 1,1-diethylpropyl, 1,1-dimethylbutyl, 1-methyl-1-ethylbutyl, 1,1-diethyl butyl, 1,1-dimethylpentyl, 1-methyl-1-ethylpentyl, 1,1-diethylpentyl, 1,1-dimethylhexyl, 1-methyl-1-ethylhexyl, 1,1-diethylhexyl, 1-methyl-1-cyclopentyl, 1-ethyl-1-cyclopentyl, 1-propyl-1-cyclopentyl, 1-butyl-1-cyclopentyl, 1-methyl-1-cyclohexyl, 1-ethyl-1-cyclohexyl, 1-propyl-1-cyclohexyl, 1-butyl-1-cyclohexyl, 2-methyl-2-adamantyl, 2-ethyl-2-adamantyl, 2-propyl-2-adamantyl, 2-butyl-2-adamanteyl, 2-isopropyl-2-adamantyl 1,1-dimethyl-3-oxobutyl, 1-ethyl-1-methyl-3-oxobutyl, 1-methyl-1-cyclohexyl-3-oxobutyl or 1,1-dimethyl-3-oxopentyl, tetrahydropyran-2-yl groups.

Examples of R⁵³ include, but are not limited to, a hydrogen atom, methyl, ethyl, propyl, isopropyl, n-butyl, sec-butyl, tert-butyl, cyclohexyl, cyclopentyl, octyl, cyclooctyl, cyclononyl, cyclodecyl, norbornyl, isobornyl, adamantyl, adamantylmethylene, tricyclo[5,2,1,0^{2.6}]decanemethylene or tetracyclo[4,4,0,1^{2,5},17,10]dodecyl groups.

Examples of R⁵⁴ include, but are not limited to, methyl, ethyl, propyl, isopropyl, n-butyl, sec-butyl, tert-butyl, cyclohexyl, cyclopentyl, octyl, cyclooctyl, cyclononyl, cyclodecyl, norbornyl, isobornyl, adamantyl, adamantylmethylene, tricyclo[5,2,1,0^{2.6}]decanemethylene, tetracyclo[4,4,0,1^{2,5},^{17,10}]dodecyl groups.

Examples of R³¹, R³², R³³, R³⁴, R³⁵, R³⁶ and R³⁷ include, but are not limited to, methyl, ethyl, propyl, isopropyl, n-butyl, sec-butyl, tert-butyl, cyclohexyl, cyclopentyl, octyl, cyclooctyl, cyclononyl, cyclodecyl, norbornyl, isobornyl, adamantyl, adamantylmethylene, tricyclo[5,2,1,0^{2.6}]decanemethylene, tetracyclo[4,4,0,1^{2,5},^{17,10}]dodecyl, trifluoromethyl, difluoromethyl, 2,2,2-trifluoroethyl, pentafluoroethyl, 3,3,3-trifluoropropyl, 1,1,1,3,3,3-hexafluoroisopropyl, 3,3,3,4,4,4-hexafluorobutyl, 3,3,3,4,4,4,5,5,5-nonafluoropentyl, 3,3,3,4,4,4,5,5,5,6,6,6-dodecafluorohexyl, 3,3,3,4,4,4,5,5,5,6,6,6,7,7,7-pentadedecafluoroheptyl, 3,3,3,4,4,4,5,5,5,6,6,6,7,7,7,8,8,8-octadecafluorooctyl, 1,2,2,3,3,4,4,5-octafluorocyclopentyl, 2-(octafluoro-1-trifluoromethylcyclopentyl)ethyl, ethyl-1-oxomethyl, ethyl-1-oxoethyl, ethyl-1-oxopropyl, ethyl-1-oxoisopropyl, ethyl-1-oxo-n-butyl, ethyl-1-oxo-sec-butyl, ethyl-1-oxo-tert-butyl, ethyl-1-oxo-cyclohexyl, ethyl-1-oxo-cyclopentyl, ethyl-1-oxocycloheptyl, ethyl-1-oxooctyl, ethyl-1-oxocyclooctyl, ethyl-1-oxocyclononyl, ethyl-1-oxocyclodecyl, ethyl-1-oxonorbornyl, ethyl-1-oxoisobornyl, ethyl-1-oxoadamantyl, ethyl-1-oxoadamantylmethylene, ethyl-1-oxotricyclo[5,2,1^{2,6}]decanemethylene, ethyl-1-oxotetracyclo[4,4,0,1^{2.5},1^{7,10}]dodecyl, propyl-1-oxomethyl, propyl-1-oxoethyl, butyl-1-oxomethyl, penyl-1-oxomethyl, hexyl-1-oxomethyl, heptyl-1-oxomethyl, octyl-1-oxomethyl, nonanyl-1-oxomethyl, decyl-1-oxomethyl, ethyl-1-oxo-α-methoxymethyl, ethyl-1-oxo-α-methoxyethyl, tert-butyloxycarbonylethyl, tert-butyloxycarbonylpropyl, tert-butyloxycarbonylbutyl, tert-butyloxycarbonylpentyl, tert-butyloxycarbonylhexyl, tert-butyloxycarbonylheptyl, tert-butyloxycarbonyloctyl, butyloxycarbonyloctyl, 1,1-dimethylpropyloxycarbonylethyl, 1-methyl-1-ethylpropyloxycarbonylethyl, 1,1-diethylpropyloxycarbonylethyl, 1,1-dimethylbutyloxycarbonylethyl, 1-methyl-1-ethylbutyloxycarbonylethyl, 1,1-diethyl butyloxycarbonylethyl, 1,1-dimethylpentyloxycarbonylethyl, 1-methyl-1-ethylpentyloxycarbonylethyl, 1,1-diethylpentyloxycarbonylethyl, 1,1-dimethylhexyloxycarbonylethyl, 1-methyl-1-ethylhexyloxycarbonylethyl, 1,1-diethylhexyloxycarbonylethyl, 1-methyl-1-cyclohexyloxycarbonylethyl, 1-ethyl-1-cyclohexyloxycarbonylethyl, 1-propyl-1-cyclohexyloxycarbonylethyl, 1-butyl-1-cyclohexyloxycarbonylethyl, 2-methyl-2-adamantyloxycarbonylethyl, 2-ethyl-2-adamantyloxycarbonylethyl, 2-propyl-2-adamantyloxycarbonylethyl, 2-butyl-2-adamanteyloxycarbonylethyl, 2-isopropyl-2-adamantyloxycarbonylethyl 1,1-dimethyl-3-oxobutyl, 1-ethyl-1-methyl-3-oxobutyl, 1-methyl-1-cyclohexyl-3-oxobutyloxycarbonylethyl, 1,1-dimethyl-3-oxopentyloxycarbonylethyl, tetrahydropyran-2-yloxycarbonylethyl, (1,1,1-trifluoro-2-fluormethyl)butyloxy, (1,1,1-trifluoro-2-fluormethyl)butyloxymethyl, (1,1,1-trifluoro-2-fluormethyl)butyloxyethyl, (1,1,1-trifluoro-2-fluormethyl)butyloxypropyl, (1,1,1-trifluoro-2-fluormethyl)butyloxybutyl, (1,1,1-trifluoro-2-fluormethyl)pentyloxymethyl, (1,1,1-trifluoro-2-fluormethyl)hexyloxymethyl, (1,1,1-trifluoro-2-fluormethyl)heptaloxymethyl, (1,1,1-trifluoro-2-fluormethyl)octaloxymethyl, (1,1,1-trifluoro-2-difluormethyl)butyloxymethyl, (1,1,1-trifluoro-2-difluormethyl)pentaloxymethyl, (1,1,1-trifluoro-2-difluormethyl)hexyloxymethyl, (1,1,1-trifluoro-2-difluormethyl)heptaloxy, (1,1,1-trifluoro-2-trifluormethyl)butyloxymethyl, (1,1,1-trifluoro-2-trifluormethyl)pentaloxymethyl, (1,1,1-trifluoro-2-trifluormethyl) hexyloxymethyl, (1,1,1-trifluoro-2-trifluormethyl) heptaloxymethyl, acetyloxyethyl, acetyloxypropyl, acetyloxybutyl, acetyloxypentyl, acetyloxyhexyl, acetyloxyheptyl, acetyloxyoctyl, ethylcarbonyloxyethyl, ethylcarbonyloxypropyl or ethylcarbonyloxybutyl, propylcarbonyloxyethyl groups.

R³⁸, R³⁹, and R⁴⁰ are independently a linear, branched or cyclic C₁-C₂₀ alkyl group, linear branched or cyclic fluoroalkyl group, substituted or unsubstituted C₃-C₂₀ alicyclic group, Structure XII or Structure XIII

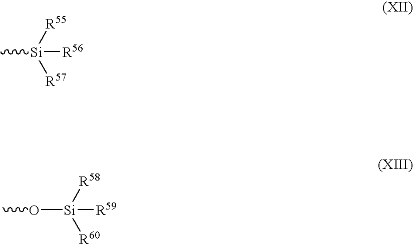

wherein R⁵⁵, R⁵⁶, R⁵⁷, R⁵⁸, R⁵⁹, and R⁶⁰ are independently a linear, branched or cyclic C₁-C₂₀ alkyl group, a linear branched or cyclic fluoroalkyl group, or a substituted or unsubstituted C₃-C₂₀ alicyclic group;

R⁴¹ and R⁴² are independently a C₁-C₃ alkylene group and R⁴³, R⁴⁴, R⁴⁵ and R⁴⁶ are independently a C₁-C₁₀ linear or cyclic alkyl group, a C₆-C₁₀ substituted or unsubstituted aryl group, a C₁-C₈ alkoxy methyl group or a C₁-C₈ alkoxy ethyl group. Examples of R⁴¹ and R⁴² include, but are not limited to, a methylene, ethylene, and propylene group, with a methylene group being more preferred. Examples of R⁴³, R⁴⁴, R⁴⁵ and R⁴⁶ groups are, but are not limited to, methyl, ethyl, propyl, isopropyl, cyclopropyl, cyclopentyl, cyclohexyl, phenyl, 4-methylphenyl, methoxy methyl, ethoxy methyl and methoxy ethyl;

R⁴⁷, R⁴⁸ and R⁴⁹ are independently linear, branched or cyclic C₁-C₂₀ alkyl or alicyclic groups, partially substituted or fully substituted cyclic C₁-C₂₀ alkyl or alicyclic groups, or substituted or unsubstituted C₆-C₂₀ aryl groups; m is an integer of from about 2 to about 10. Preferably m is 2 to 6, more preferred 2-3, most preferred 3.

Examples of R⁴⁷, R⁴⁸ and R⁴⁹ include, but are not limited to, methyl, trifluoromethyl, ethyl, n-propyl, isopropyl, n-butyl, isobutyl, sec-butyl, tert-butyl, cyclopentyl, cyclohexyl, heptyl, isooctyl, cyclooctyl, nonyl, decyl, pendecyl, eicosyl, hydroxycyclohexyl, dihydroxycyclohexyl, bicyclo[2.2.1]heptyl, hydroxybicyclo[2.2.1]heptyl, carboxybicyclo[2.2.1]heptyl, phenyl, tolyl, and naphthyl. Preferred examples of R⁴⁷, R⁴⁸ and R⁴⁹ include, but are not limited to, methyl, ethyl, n-propyl, isopropyl, n-butyl, isobutyl, sec-butyl, tert-butyl, cyclopentyl, cyclohexyl, cyclooctyl, dihydroxycyclohexyl, bicyclo[2.2.1]heptyl, hydroxybicyclo[2.2.1]heptyl, carboxybicyclo[2.2.1]heptyl, and naphthyl.

Examples of silicon-containing monomeric units include, but are not limited to the following structures:

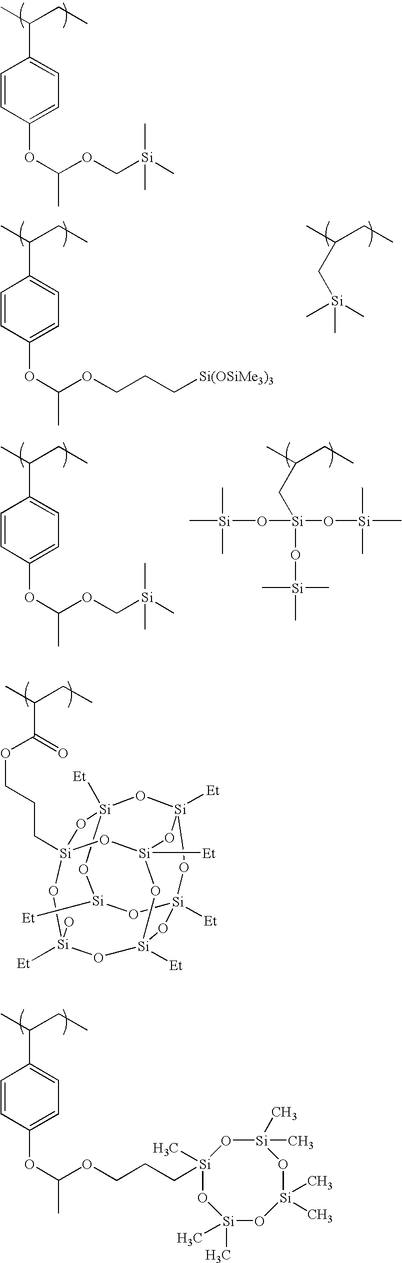

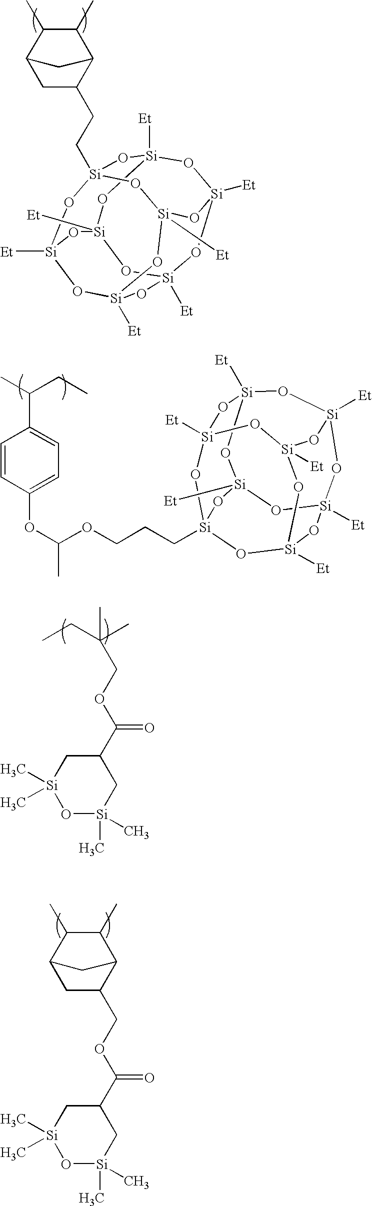

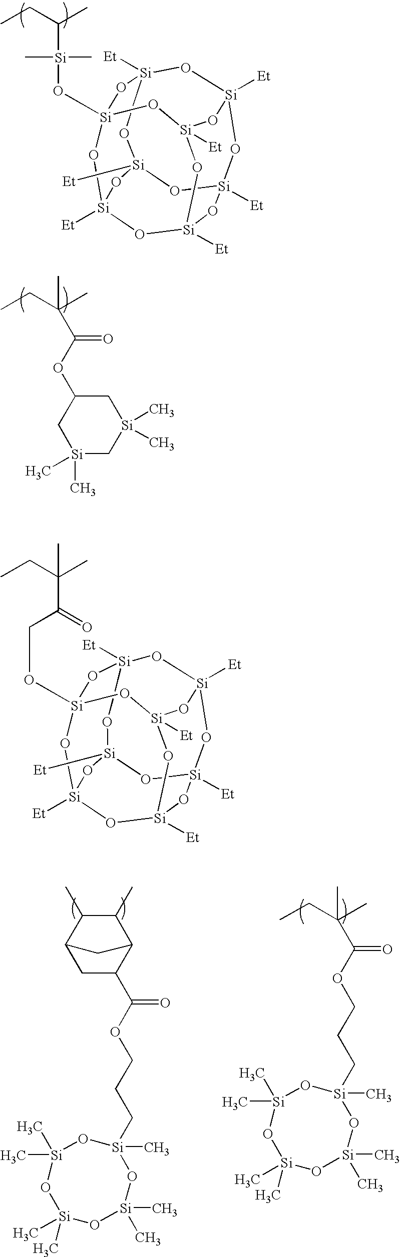

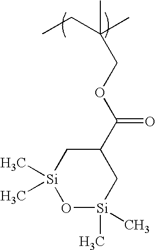

In addition the polymer may optionally comprise one or more property enhancing co-monomeric units for the purpose of optimizing functional characteristics of the final polymer, such as incorporating polar groups to promote solubility of the polymer in the casting solvent, balancing the polymer's optical parameters to improve lithographic behavior or optimizing the polymer's etch selectivity. Alkali solubilizing monomeric units as described above may be used to change the dissolution characteristics of the polymer. Suitable modifying monomers include radical polymerizable vinyl monomers such as acrylates, methacrylates, vinyl ethers, vinyl esters, substituted and unsubstituted styrenes and the like. Examples of preferred modifying monomers include, but are not limited to, methyl acrylate, methyl methacrylate, hydroxyethyl acrylate, methyl vinyl ether, ethyl vinyl ether, ethyleneglycol vinyl ether, styrene, t-butyl styrene, and hydroxy styrene.

Additional examples of preferred modifying monomeric units include, but are not limited Structures Structure XIV-XVII:

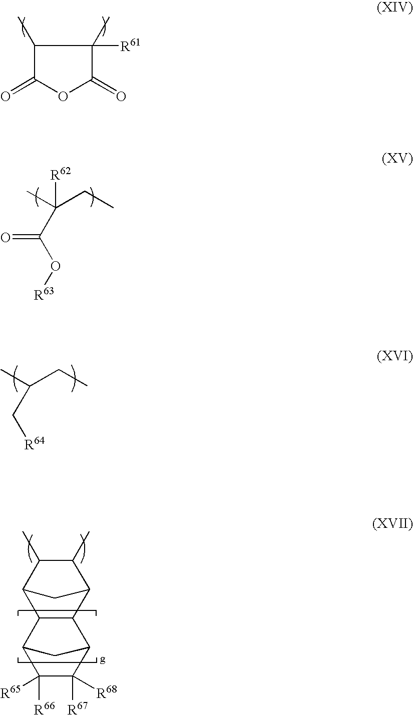

wherein R⁶¹ is a hydrogen atom, a C₁-C₄ linear or branched alkyl or a linear or branched C₁-C₄ alkoxy group; R⁶² is a hydrogen atom, a C₁-C₃ linear or branched alkyl group, or a linear or branched C₁-C₃ perfluorinated alkyl group; R⁶³ is a C₁-C₂₀ linear, branched, or cyclic alkyl group, C₇-C₂₀ alicyclic alkyl group, a C₁-C₂₀ linear, branched, or cyclic ether group, a C₃-C₈ lactone group or a C₆-C₁₀ aryl group; and R⁶⁴ is a C₁-C₈ alkoxy, a C₁-C₈ alkyl ester, a C₁-C₈ alkyl carboxylate, or hydroxyl group; R⁶⁵, R⁶⁶, R⁶⁷ and R⁶⁸ independently represent a hydrogen atom, halogen atom, a hydroxyl group, a C₁-C₁₀ substituted or unsubstituted linear, branched or cyclic alkyl group, —(CH₂)ₖC(O)OR⁶⁹, —(CH₂)ₖ—OR⁷⁰, —(CH₂)ₖ—OC(O)R⁷¹, —(CH₂)ₖ—C(O)R⁷², or —(CH₂)ₖ—OC(O)OR⁷ wherein R⁶⁹, R⁷⁰, R⁷¹, R⁷², and R⁷³ independently represent a hydrogen atom or a C₁-C₁₀ linear branched or cyclic alkyl group; k is an integer from 0 to about 5, preferably 0 or 1; and g is an integer from 0 to about 5, preferably from 0 to 2.

It should be noted that any two of the R⁶⁵, R⁶⁶, R⁶⁷ and R⁶⁸ groups may be bonded to each other to form a cyclic structure. This cyclic structure may be the condensed from two carboxylic acid groups (anhydride).

Examples of R⁶¹ include, but are not limited to, methyl, ethyl, propyl, methoxy, ethoxy, and isopropyl. Examples of monomers yielding monomeric units of Structure XIV after polymerization include, but are not limited to, maleic anhydride or citraconic anhydride.

Examples of R⁶² groups include, but are not limited to, a hydrogen atom, methyl, ethyl, isopropyl, trifluoroethyl or trifluoromethyl groups. Examples of preferred R⁶² groups include a hydrogen atom, methyl or trifluoromethyl groups. Examples of suitable R⁶³ groups include, but are not limited to, a hydrogen atom, methyl, ethyl, cyclohexyl, cyclopentyl, isobornyl, adamantyl, 3-hydroxy-1-adamantyl, 3,5-dihydroxy-1-adamantyl, tetrahydrofuranyl, tetrahydrofuran-2-ylmethyl, 2-oxotetrahydrofuran-3-yl, 5-oxotetrahydrofuran-3-yl, 5-oxo-4-oxatricyclo[4.2.1.0^{3,7}]non-9-yl, 6-hydroxy norbornyl, decahydronaphthyl, phenyl, or naphthyl groups. Preferred examples of R⁶³ are methyl, ethyl, cyclohexyl, adamantyl, tetrahydrofuranyl, or naphthyl groups. Examples of suitable monomers yielding monomeric units of Structure XV after polymerization include, but are not limited to, methyl methacrylate, adamantyl methacrylate, cyclohexyl methacrylate, hydroxyethyl methacrylate, phenyl acrylate, methyl trifluoromethylacrylate or naphthyl methacrylate.

Examples of R⁶⁴ groups include, but are not limited to, a hydrogen atom, methyl, ethyl, isopropyl, methoxy, ethoxy, methyl carboxylate, ethyl carboxylate, and acetate. Examples of preferred R⁶⁴ groups are methoxy, ethoxy, methyl carboxylate, ethyl carboxylate, and acetate. Examples of monomers yielding monomeric units of Structure XVI after polymerization include, but are not limited to, propene, butene, allyl alcohol, allyl acetate, vinyl acetic acid, methyl vinyl acetic acid or methyl allyl ether.

Examples of R⁶⁹, R⁷⁰, R⁷¹, R⁷² and R⁷³ groups include, but are not limited to, a hydrogen atom, fluoride atom, methyl, ethyl, isopropyl, butyl, tert-butyl, iso butyl, pentyl, neo-pentyl, iso-pentyl, cyclopentyl, hexyl, cyclohexyl, heptyl, octyl, nonyl, decyl and trifluoromethyl.

Examples of R⁶⁵, R⁶⁶, R⁶⁷ and R⁶⁸ groups include, but are not limited to, a hydrogen atom, fluoride atom, hydroxyl, methyl, ethyl, isopropyl, butyl, tert-butyl, iso butyl, pentyl, neo-pentyl, iso-pentyl, cyclopentyl, hexyl, cyclohexyl, heptyl, octyl, nonyl, decyl, trifluoromethyl, methoxy, ethoxy, propoxy, ethoxy propyl, methoxy ethyl, methoxycarbonyl, ethoxycarbonyl, isopropoxycarbonyl, 3-propyl ethoxycarbonyl, 2-ethyl ethoxycarbonyl, cyclopentyl ethyl carboxylate, methylene acetate, heptan-3-onyl, acetyl, and methylene propyl carbonate.

Examples of monomers yielding monomeric units of Structure XVII after polymerization include, but are not limited to, bicyclo[2.2.1]hept-2-ene, 5-fluorobicyclo[2.2.1]hept-2-ene, bicyclo[2.2.1]hept-5-en-2-ol, 5-methylbicyclo[2.2.1]hept-2-ene, ethyllbicyclo[2.2.1]hept-2-ene, propylbicyclo[2.2.1]hept-2-ene, butylbicyclo[2.2.1]hept-2-ene, decylbicyclo[2.2.1]hept-2-ene, 5-(1-methylethyl)bicyclo[2.2.1]hept-2-ene, 5-tert-butylbicyclo[2.2.1]hept-2-ene, 5-(3-methylbutyl)bicyclo[2.2.1]hept-2-ene, 4-bicyclo[2.2.1]hept-5-en-2-ylbutan-2-ol, 5-cyclopentylbicyclo[2.2.1]hept-2-ene, tricyclo[5.2.1.02,6]dec-8-ene, 2-(trifluoromethyl)bicyclo[2.2.1]heptane, bicyclo[2.2.1]hept-5-ene-2-carboxylic acid, bicyclo[2.2.1]hept-5-en-2-ylacetic acid, 3-bicyclo[2.2.1]hept-5-en-2-ylpropanoic acid, 3-bicyclo[2.2.1]hept-5-en-2-ylbutanoic acid, 3-bicyclo[2.2.1]hept-5-en-2-yldecanoic acid, methyl bicyclo[2.2.1]hept-5-ene-2-carboxylate, ethyl bicyclo[2.2.1]hept-5-ene-2-carboxylate, methyl bicyclo[2.2.1]hept-5-en-2-ylacetate, ethyl bicyclo[2.2.1]hept-5-en-2-ylacetate, propyl bicyclo[2.2.1]hept-5-en-2-ylacetate, 1-methylethyl bicyclo[2.2.1]hept-5-en-2-ylacetate, tert-butyl bicyclo[2.2.1]hept-5-en-2-ylacetate, 5-methoxybicyclo[2.2.1]hept-2-ene, 5-ethoxybicyclo[2.2.1]hept-2-ene, 5-propoxybicyclo[2.2.1]hept-2-ene, 5-butoxybicyclo[2.2.1]hept-2-ene, 5-tert-butoxybicyclo[2.2.1]hept-2-ene, 5-decyloxybicyclo[2.2.1]hept-2-ene, 5-(methoxymethyl)bicyclo[2.2.1]hept-2-ene, 5-(methoxyethyl)bicyclo[2.2.1]hept-2-ene, 5-(methoxypropyl)bicyclo[2.2.1]hept-2-ene, 5-[(1-methylethoxy)methyl]bicyclo[2.2.1]hept-2-ene, 5-[(cyclopentyloxy)methyl]bicyclo[2.2.1]hept-2-ene, bicyclo[2.2.1]hept-5-en-2-ylmethanol, bicyclo[2.2.1]hept-5-en-2-yl acetate, bicyclo[2.2.1]hept-5-en-2-yl propanoate, bicyclo[2.2.1]hept-5-en-2-yl 2-methylpropanoate, bicyclo[2.2.1]hept-5-en-2-yl propanoate, bicyclo[2.2.1]hept-5-en-2-ylmethyl propanoate, 1-bicyclo[2.2.1]hept-5-en-2-ylethanone, 1-bicyclo[2.2.1]hept-5-en-2-ylpropan-1-one, 1-bicyclo[2.2.1]hept-5-en-2-ylpropan-2-one, 1-bicyclo[2.2.1]hept-5-en-2-ylbutan-2-one, 1-bicyclo[2.2.1]hept-5-en-2-ylpentan-2-one, 1-bicyclo[2.2.1]hept-5-en-2-yl-3-methylpentan-2-one, 1-bicyclo[2.2.1]hept-5-en-2-yl-3-methylbutan-2-one, 1-bicyclo[2.2.1]hept-5-en-2-yl-3,3-dimethylbutan-2-one, 3,3-dimethyl-1-(3-methylbicyclo[2.2.1]hept-5-en-2-yl)butan-2-one bicyclo[2.2.1]hept-5-en-2-yl methyl carbonate, bicyclo[2.2.1]hept-5-en-2-yl 1-methylethyl carbonate, bicyclo[2.2.1]hept-5-en-2-ylmethyl 1-methylethyl carbonate, 4′,5′-dihydrospiro[b]cyclo[2.2.1]hept-5-ene-2,3′-furan]-2′-one, tetracyclo[4.4.0.1^{2,5}1,^{7,10}]docec-8-ene-3-ol, tetracyclo[4.4.0.1^{2,5}.1^{7,10}]docec-8-ene-3-yl-acetate, tetracyclo[4.4.0.1^{2,5}.1^{7,10}]docec-8-ene-3-ylmethanol, tetracyclo[4.4.0.1^{2,5}.1^{7,10}]docec-8-ene-3-ylethanol, hexacyclo[8.4.1^{2,5}.1^{7,14}.1^{9,12}.0^{1,6}.0^{8,13}]tetradeca-10-ene-3-ylacetate, hexacyclo[8.4.1^{2,5}.1^{7,14}.1^{9,12}.0^{1,6}.0^{8,13}]tetradeca-10-ene-3-ylmethanol, hexacyclo[8.4.1^{2,5}.1^{7,14}.1^{9,12}.0^{1,6}.0^{8,13}]tetradeca-10-ene-3-ylmethanol, hexacyclo[8.4.1^{2,5}.1^{7,14}.1^{9,12}.0^{1,6}.0^{8,13}]tetradeca-10-ene-3-ylethanol, and 10-methylhexacyclo[8.4.1^{2,5}.1^{7,14}.1^{9,12}.0^{1,6}.0^{8,13}]tetradeca-10-ene-3-ylacetate.

Examples of suitable silicon-containing polymers can be found in U.S. Pat. Nos. 6,146,793, 6,165,682, 6,340,734, 6,028,154, 6,042,989, 5,882,844, 5,691,396, 5,731,126, 5,985,524, 6,531,260, 6,590,010, 6,916,543 and 6,929,897, which are incorporated herein by reference. Other suitable polymers are disclosed in JP Patent No. 3736606. The silicon content may be contained in the polymer before coating as in the above references or the polymer may be silylated after coating as in U.S. Pat. Nos. 6,306,990 and 6,110,637, which are incorporated herein by reference.

Additional examples of suitable polymers include, but are not limited to,

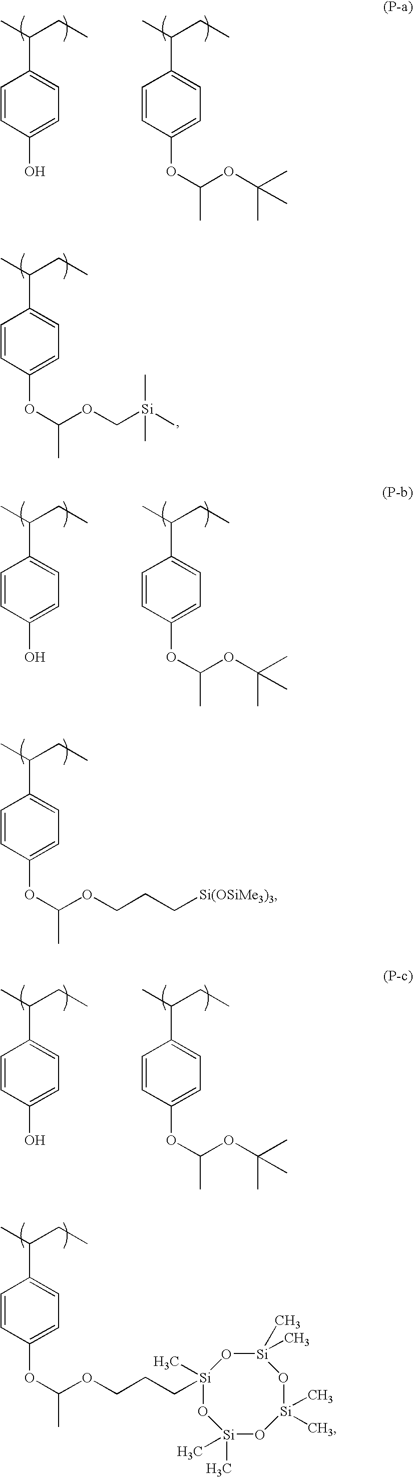

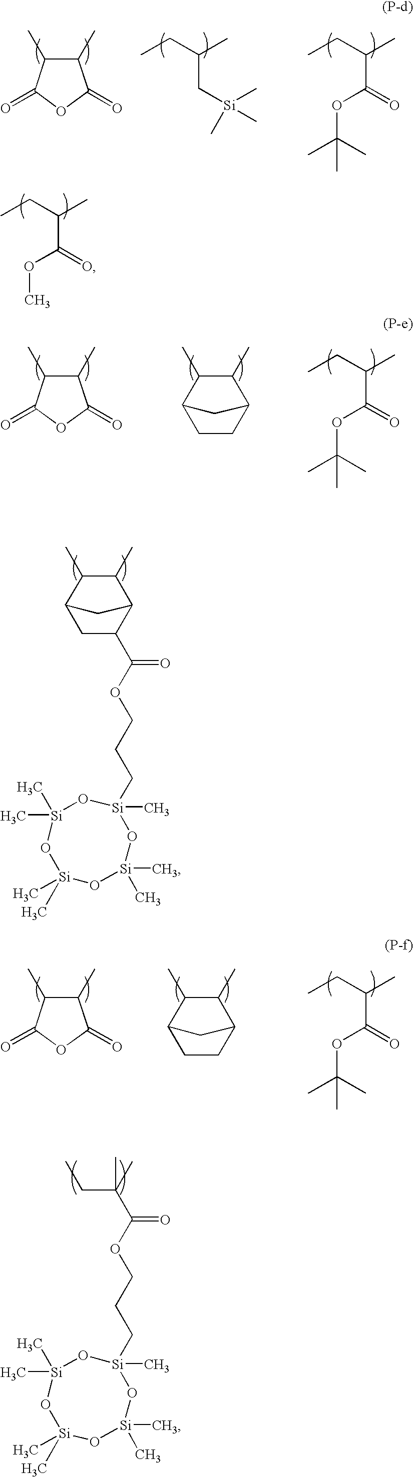

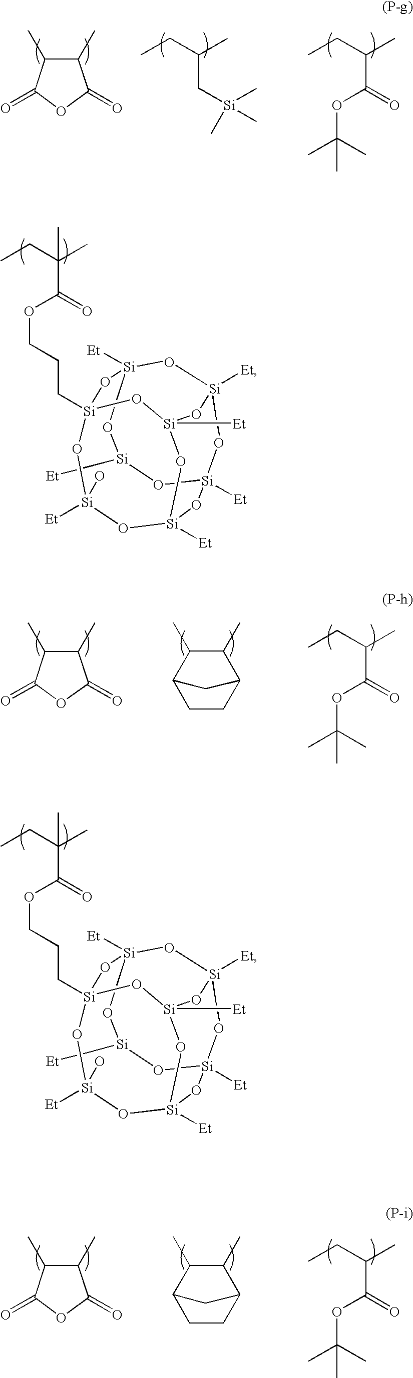

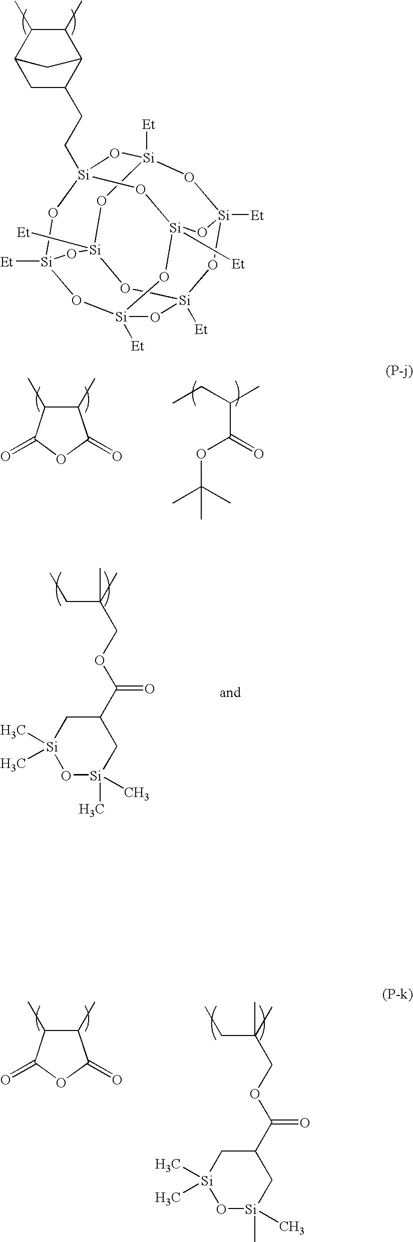

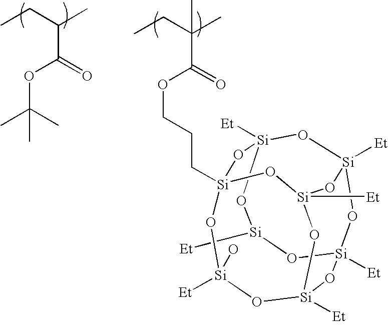

Suitable silicon-containing polymers also include acrylic polymers such as those described in U.S. Pat. No. 6,146,793 and U.S. Pat. No. 6,165,682 herein incorporated by reference.

The silicon-containing polymer comprises from about 75 wt % to about 99 wt % of the total solids content of the photosensitive composition. The preferred concentration is from about 78 wt % to about 92 wt % and the more preferred concentration is from about 82 wt % to about 90 wt %. Suitable polymers are those with silicon content of about 0.2 wt % to about 15 wt % silicon by weight. Preferred polymers are those with silicon content from about 1 wt % to about 10 wt % silicon and the more preferred silicon content of the polymer is from about 3 wt % to about 10 wt %.

The photosensitive composition may optionally comprise one or more dissolution inhibitors (DI). Dissolution inhibitors useful for this disclosure have been studied and are known to those skilled in the art. These compounds can be monomers or oligomers with a weight average molecular weight of no more than 3000. For example, dissolution inhibitors (DIs) can be aromatic compounds containing acid sensitive carboxylic acid esters, carbonate or hydroxyl groups as described in SPIE Proc. 920, pg. 42 (1988), SPIE Proc. 2724, pg. 174 (1996) and U.S. Pat. No. 6,962,766, such as naphthalene-2-carboxylic acid tert-butyl ester, t-BOC-bisphenol A, t-BOC-trisphenol, or alicyclic or polycyclic structures with at least one acid sensitive substituent as described in SPIE Proc. 2724. pg. 355 (1996), U.S. Pat. Nos. 6,927,009 and 6,962,766, such as cholates and acid sensitive adamantylcarboxylic acid esters. For applications that utilize actinic light below 220 nm non-aromatic dissolution inhibitors are preferred.

If used the dissolution inhibitor is typically present in the amount of about 3 wt % to about 20 wt % and more preferably about 5 wt % to about 15 wt % based on the dry weight of the photosensitive composition.

The photoactive compound capable of generating a strong acid upon exposure to a source of high energy radiation is commonly referred to as a photoacid generator, or PAG. Any suitable photoacid generator may be used in the photosensitive compositions of the present disclosure. One skilled in the art would be able to choose the appropriate PAG based upon such factors as acidity, catalytic activity, volatility, diffusivity, and solubility. Preferred PAGs are tris(perfluoroalkylsulfonyl)methides, tris(perfluoroalkylsulfonyl)imides, and those generating perfluoroalkylsulfonic acids. Suitable classes of PAGs generating sulfonic acids include, but are not limited to, sulfonium or iodonium salts, oximidosulfonates, bissulfonyldiazomethanes, and nitrobenzylsulfonate esters. Suitable photoacid generator compounds are disclosed, for example, in U.S. Pat. Nos. 5,558,978, 5,468,589, 6,855,476, and 6,911,297 which are incorporated herein by reference.

Additional examples of suitable photoacid generators for use in this disclosure include, but are not limited to, triphenylsulfonium perfluorooctanesulfonate, triphenylsulfonium perfluorobutanesulfonate, methylphenyldiphenylsulfonium perfluorooctanesulfonate, 4-n-butoxyphenyldiphenylsulfonium perfluorobutanesulfonate, 2,4,6-trimethylphenyldiphenylsulfonium perfluorobutanesulfonate, 2,4,6-trimethylphenyldiphenylsulfonium benzenesulfonate, 2,4,6-trimethylphenyldiphenylsulfonium 2,4,6-triisopropylbenzenesulfonate, phenylthiophenyldiphenylsulfonium 4-dodecylbenzensulfonic acid, tris(-t-butylphenyl)sulfonium perfluorooctanesulfonate, tris(-t-butylphenyl)sulfonium perfluorobutanesulfonate, tris(-t-butylphenyl)sulfonium 2,4,6-triisopropylbenzenesulfonate, tris(-t-butylphenyl)sulfonium benzenesulfonate, and phenylthiophenyldiphenylsulfonium perfluorooctanesulfonate.

Examples of suitable iodonium salts for use in this disclosure include, but are not limited to, diphenyl iodonium perfluorobutanesulfonate, bis-(t-butylphenyl)iodonium perfluorobutanesulfonate, bis-(t-butylphenyl)iodonium, perfluorooctanesulfonate, diphenyl iodonium perfluorooctanesulfonate, bis-(t-butylphenyl)iodonium benzenesulfonate, bis-(t-butylphenyl)iodonium 2,4,6-triisopropylbenzenesulfonate, and diphenyliodonium 4-methoxybenzensulfonate.

Examples of tris(perfluoroalkylsulfonyl)methide and tris(perfluoroalkylsulfonyl)imide PAGs that are suitable for use in the present disclosure can be found in U.S. Pat. Nos. 5,554,664 and 6,306,555, each of which is incorporated herein in its entirety. Additional examples of PAGs of this type can be found in Proceedings of SPIE, Vol. 4690, p. 817-828 (2002). Suitable methide and imide PAGs include, but are not limited to, triphenylsulfonium tris(trifluoromethylsulfonyl)methide, methylphenyldiphenylsulfonium tris(perfluoroethylsulfonyl)methide, triphenylsulfonium tris(perfluorobutylsulfonyl)methide, triphenylsulfonium bis(trifluoromethylsulfonyl)imide, triphenylsulfonium bis(perfluoroethylsulfonyl)imide, and triphenylsulfonium bis(perfluorobutylsulfonyl)imide.

Further examples of suitable photoacid generators for use in this disclosure are bis(p-toluenesulfonyl)diazomethane, methylsulfonyl p-toluenesulfonyldiazomethane, 1-cyclo-hexylsulfonyl-1-(1,1-dimethylethylsulfonyl)diazomethane, bis(1,1-dimethylethylsulfonyl)diazomethane, bis(1-methylethylsulfonyl)diazomethane, bis(cyclohexylsulfonyl)diazomethane, 1-p-toluenesulfonyl-1-cyclohexylcarbonyldiazomethane, 2-methyl-2-(p-toluenesulfonyl)propiophenone, 2-methanesulfonyl-2-methyl-(4-methylthiopropiophenone, 2,4-methyl-2-(p-toluenesulfonyl)pent-3-one, 1-diazo-1-methylsulfonyl-4-phenyl-2-butanone, 2-(cyclohexylcarbonyl-2-(p-toluenesulfonyl)propane, 1-cyclohexylsulfonyl-1-cyclohexylcarbonyldiazomethane, 1-diazo-1-cyclohexylsulfonyl-3,3-dimethyl-2-butanone, 1-diazo-1-(1,1-dimethylethylsulfonyl)-3,3-dimethyl-2-butanone, 1-acetyl-1-(1-methylethylsulfonyl)diazomethane, 1-diazo-1-(p-toluenesulfonyl)-3,3-dimethyl-2-butanone, 1-diazo-1-benzenesulfonyl-3,3-dimethyl-2-butanone, 1-diazo-1-(p-toluenesulfonyl)-3-methyl-2-butanone, cyclohexyl 2-diazo-2-(p-toluenesulfonyl)acetate, tert-butyl 2-diazo-2-benzenesulfonylacetate, isopropyl-2-diazo-2-methanesulfonylacetate, cyclohexyl 2-diazo-2-benzenesulfonylacetate, tert-butyl 2 diazo-2-(p-toluenesulfonyl)acetate, 2-nitrobenzyl p-toluenesulfonate, 2,6-dinitrobenzyl p-toluenesulfonate, 2,4-dinitrobenzyl p-trifluoromethylbenzenesulfonate.

More preferred PAGs are triarylsulfonium perfluoroalkylsulfonates and triarylsulfonium tris(perfluoroalkylsulfonyl)methides. Most preferred PAGs are triphenylsulfonium perfluorooctanesulfonate (TPS-PFOS), triphenylsulfonium perfluorobutanesulfonate (TPS-Nonaflate), methylphenyldiphenylsulfonium perfluorooctanesulfonate (TDPS-PFOS), tris(-t-butylphenyl)sulfonium perfluorobutanesulfonate (TTBPS-Nonaflate), triphenylsulfonium tris(trifluoromethylsulfonyl)methide (TPS-C1), and methylphenyldiphenylsulfonium tris(perfluoroethylsulfonyl)methide (TDPS-C2).

The total photoacid generator content of the photosensitive composition is from about 0.05 wt % to about 20 wt % of the total solids content. The preferred range is from about 1 wt % to about 15 wt %. The photoacid generator may be used alone or in combination with one or more photoacid generators. The percentage of each PAG in the photoacid generator mixture is between about 10 wt % to about 90 wt % of the total photoacid generator mixture. Preferred photoacid generator mixtures contain about 2 or 3 photoacid generators. Such mixtures may be of the same class or different classes. Examples of preferred mixtures include sulfonium salts with bissulfonyldiazomethane compounds, sulfonium salts and imidosulfonates, and two sulfonium salts.

The choice of solvent for the photosensitive composition and the concentration thereof depends principally on the type of functionalities incorporated in the acid labile polymer, the photoacid generator, and the coating method. The solvent should be inert, should dissolve all the components in the photosensitive composition, should not undergo any chemical reaction with the components and should be removable on drying after coating. Any suitable solvent or mixture of solvents may be used in the photosensitive composition of the present disclosure. Examples of suitable solvents include, but are not limited to, ketones, ethers and esters, such as methyl ethyl ketone, methyl isobutyl ketone, 2-heptanone, cyclopentanone, cyclohexanone, 2-methoxy-1-propylene acetate, 2-methoxyethanol, 2-ethoxyethanol, 2-ethoxyethyl acetate, propylene glycol monomethyl ether, 1-methoxy-2-propyl acetate, 1,2-dimethoxyethane ethyl acetate, cellosolve acetate, propylene glycol monomethyl ether acetate, methyl lactate, ethyl lactate, methyl pyruvate, ethyl pyruvate, methyl 3-methoxypropionate, ethyl 3-methoxypropionate, N-methyl-2-pyrrolidone, 1,4-dioxane, ethylene glycol monoisopropyl ether, diethylene glycol monoethyl ether, diethylene glycol monomethyl ether, diethylene glycol dimethyl ether, and the like. More preferred solvents are propylene glycol monomethyl ether, 2-heptanone, and propylene glycol monomethyl ether acetate. Most preferred solvents are 2-heptanone and propylene glycol monomethyl ether acetate.

Base additives may also be added to the photosensitive composition. One purpose of the base additive is to scavenge protons present in the photosensitive composition prior to being irradiated by actinic radiation. The base prevents attack and cleavage of the acid labile groups by undesirable acids, thereby increasing the performance and stability of the photosensitive composition. In addition, the base can act as a diffusion control agent to prevent the photogenerated acid from migrating too far after exposure and lowering resolution. The percentage of base in the photosensitive composition should be significantly lower than the photoacid generator or otherwise the photosensitivity becomes too low. The preferred range of the base compounds, when present, is from about 3 wt % to about 50 wt % of the photoacid generator compound. Suitable examples of base additives include, but are not limited to, cyclopropylamine, cyclobutylamine, cyclopentylamine, dicyclopentylamine, dicyclopentylmethylamine, dicyclopentylethylamine, cyclohexylamine, dimethylcyclohexylamine, dicyclohexylamine, dicyclohexylmethylamine, dicyclohexylethylamine, dicyclohexylbutylamine, cyclohexyl-t-butylamine, cycloheptylamine, cyclooctylamine, 1-adamantanamine, 1-dimethylaminoadamantane, 1-diethylaminoadamantane, 2-adamantanamine, 2-dimethylaminoadamantane, 2-aminonorbornene, and 3-noradamantanamine, 2-methylimidazole, tetramethyl ammonium hydroxide, tetrabutylammonium hydroxide, triisopropylamine, triocylamine, tridodecylamine, 4-dimethylaminopryidine, 4,4′-diaminodiphenyl ether, 2,4,5-triphenylimidazole, 1,4-diazabicyclo[4.3.0]non-5-ene, 1,5-diazabicyclo[4.3.0]non-5-ene, 1,8-diazabicyclo[5.4.0]undec-7-ene, guanidine, 1,1-dimethylguanidine, 1,1,3,3-tetramethylguanidine, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, N-(2-aminoethyl)morpholine, trimethylimidazole, triphenylimidazole, and methyldiphenylimidazole. More preferred base additives are tridodecylamine, 2,4,5-triphenyl imidazole, 1,5-diazobicyclo[4.3.0]non-5-ene and 1,8-diazobicyclo[5.4.0]undec-7-ene.

In addition dyes may be added to the photosensitive composition to increase the absorption of the composition to the actinic radiation wavelength. The dye must not poison the photosensitive composition and must be capable of withstanding the process conditions including any thermal treatments. Examples of suitable dyes are fluorenone derivatives, anthracene derivatives or pyrene derivatives. Other specific dyes that are suitable for these photosensitive compositions are described in U.S. Pat. No. 5,593,812 incorporated herein by reference.

The photosensitive composition may further comprise conventional additives such as adhesion promoters and surfactants. One skilled in the art will be able to choose the appropriate desired additive and its concentration.

A further embodiment of this disclosure is a process for the production of relief structures on a substrate that comprises:
A) providing a substrate;
B) coating a photosensitive composition on said substrate;
C) baking the photosensitive composition to provide a photosensitive film on the substrate;
D) exposing the photosensitive film to imaging radiation;
E) developing the photosensitive film making a portion of the underlying substrate visible;
F) rinsing the coated, exposed and developed substrate;

wherein the photosensitive composition comprises a composition of Composition A), Composition B) or Composition C) as defined hereinafter in this paragraph and in paragraphs [0076] and [0077]. Composition A) comprises:
a) a polyhedral oligomeric silsesquioxane (POSS) compound selected from compounds of structures (IA)-(IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IA) to (IE) are as follows

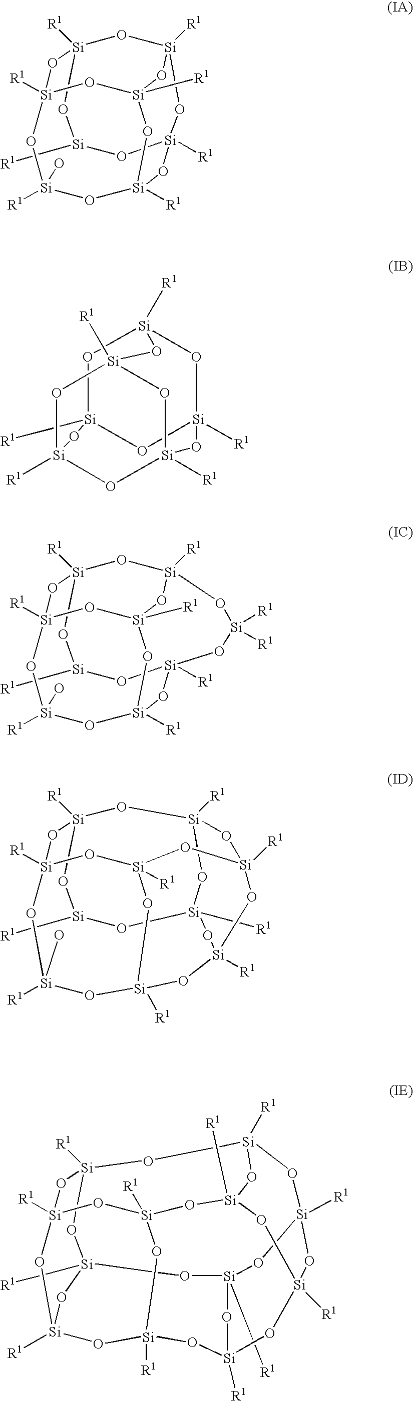

wherein each R¹ is independently a radical of formula (A)

-(J¹)_{c}-(L¹)_{d}-R² (A)

wherein c is an integer from zero to 3;
d is zero or 1;
J¹ is a substituted or unsubstituted C₁-C₁₂ linear, branched or cyclic alkylene group or a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group;
R² is selected from the group consisting of
1) —OR⁵ wherein R⁵ is either a hydrogen atom or a substituted or unsubstituted C₁-C₁₂ linear, branched or cyclic alkyl group; and
2) a cyclic anhydride group of structure (IIA) or a lactone group of structure (IIB):

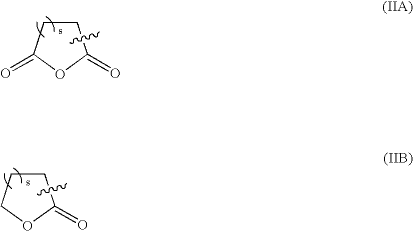

preferably structures (IIA¹) and (IIB¹)

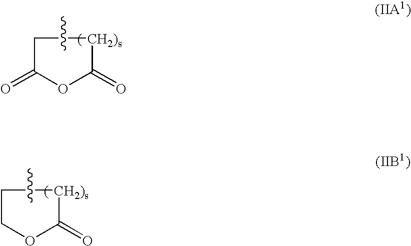

wherein s is an integer from 0 to 3 and structures (IIA), (IIA¹), (IIB) and (IIB¹) may be bonded to L¹ in one or more places.

Composition B) in this further embodiment of a process for the production of relief structures on a substrate comprises a composition of:
a) a polyhedral oligomeric silsesquioxane (POSS) compound selected from compounds of structures (IF) and (IG);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IF) and (IG) are as follows

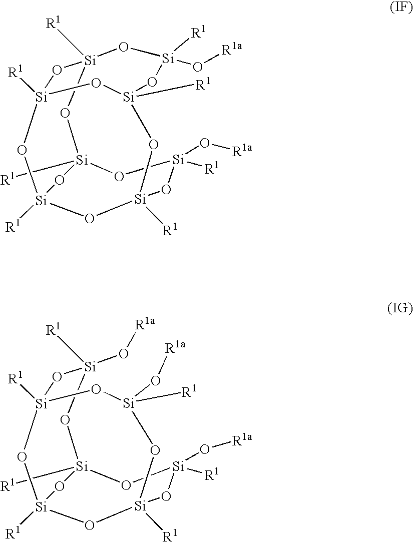

wherein each R¹ is independently a radical of formula (A)

-(J¹)_{c}-(L¹)_{d}-R² (A)

wherein c is an integer from zero to 3;
d is zero or 1;
J¹ is a substituted or unsubstituted C₁-C₁₂ linear, branched or cyclic alkylene group or a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group;
R² is selected from the group consisting of
1) a hydrogen atom;
2) —OR⁵ wherein R⁵ is either a hydrogen atom or a substituted or unsubstituted C₁-C₁₂ linear, branched or cyclic alkyl group; and
3) a cyclic anhydride group of structure (IIA) or a lactone group of structure (IIB):

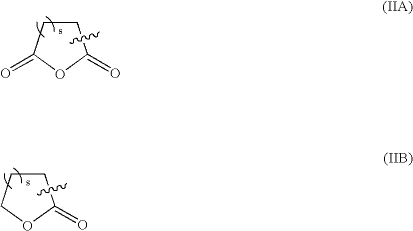

preferably structures (IIA¹) and (IIB¹)

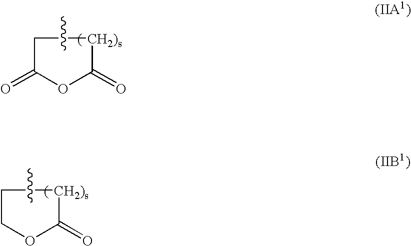

wherein s is an integer from 0 to 3 and structures (IIA), (IIA¹), (IIB) and (IIB¹) may be bonded to L¹ in one or more places;
   each R^{1a} is independently a radical of formula (B)

—(SiR⁶R⁷)-(G)ₑ-R⁸ (B)

wherein R⁶ and R⁷ are each, independently, a substituted or unsubstituted C₁-C₁₂ linear, branched or cyclic alkyl or aryl group;
G is a substituted or unsubstituted C₁-C₁₂ linear, branched, or cyclic alkylene or arylene group;
e is zero or 1;
and R⁸ is selected from the group consisting of
1) a hydrogen atom;
2) —OR⁹ wherein R⁹ is either a hydrogen atom or a substituted or unsubstituted C₁-C₁₂ linear, branched or cyclic alkyl group; and
3) a cyclic anhydride group of structure (IIIA) or a lactone group of structure (IIIB):

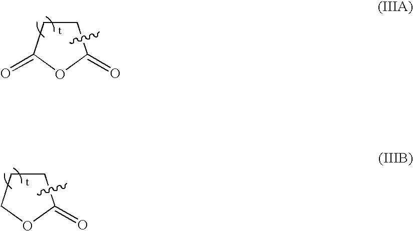

preferably structures (IIIA¹) and (IIIB¹)

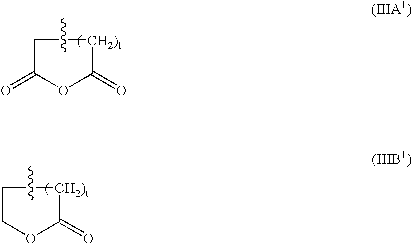

wherein t is an integer from 0 to 3 and structures (IIIA), (IIIA¹), (IIIB) and (IIIB¹) may be bonded to G in one or more places.

Composition C) in this further embodiment of a process for the production of relief structures on a substrate comprises a composition of:
a) a polyhedral oligomeric silsesquioxane (POSS) compound selected from compounds of structures (IA), (IB), (ID), and (IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IA), (IB), (ID), and (IE) are as follows

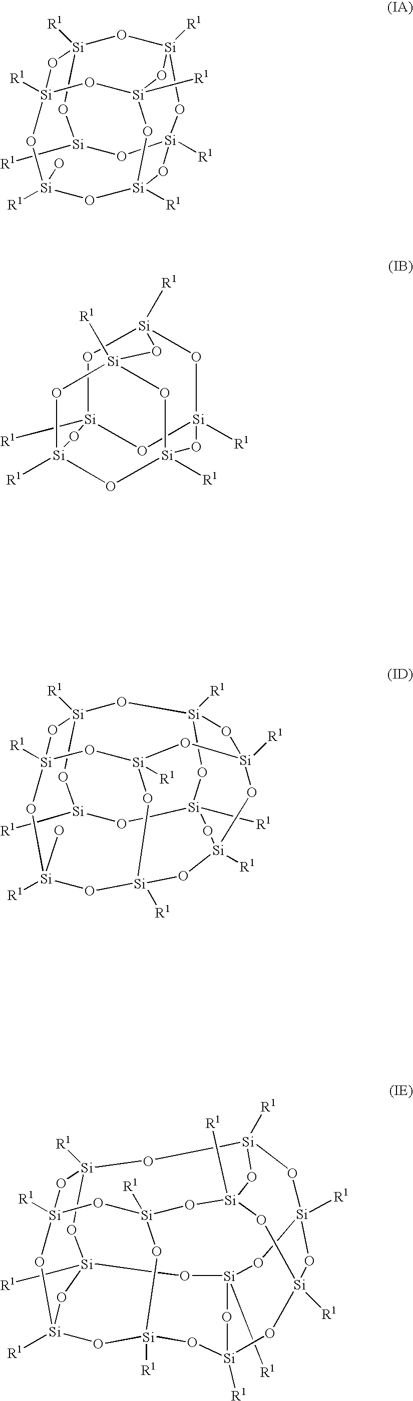

wherein each R¹ is independently a radical of formula (A)

-(J¹)_{c}-(L¹)_{d}-R² (A)

wherein c is an integer from zero to 3;
d is zero;
J¹ is a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group; and
R² is a hydrogen atom.

The substrate may be, for example, semiconductor materials such as a silicon wafer, compound semiconductor (III-V) or (II-VI) wafer, a ceramic, glass or quartz substrate. Said substrates may also contain films or structures used for electronic circuit fabrication such as organic or inorganic dielectrics, copper or other wiring metals.

The photosensitive composition is applied uniformly onto a substrate by known coating methods. For example, the coatings may be applied by spin-coating, dipping, knife coating, laminating, brushing, spraying, and reverse-roller coating. After the coating operation, the solvent is generally removed by drying. The drying step is typically a heating step called soft bake where the photosensitive composition and substrate are heated to a temperature of about 50° C. to about 150° C. for a few seconds to a few minutes; preferably for about 5 seconds to about 30 minutes depending on the thickness, the heating element and end use of the thus generated photosensitive film.

The photosensitive film thickness is optimized for lithographic performance and the need to provide plasma etch resistance for image transfer or substrate treatment. Preferably the photosensitive film has a thickness from about 80 nm to about 500 nm. A more preferred thickness range of the photosensitive film is from about 100 nm to about 250 nm. The preferred photosensitive film thickness is from 110 nm to 170 nm.

The photosensitive compositions are suitable for a number of different uses in the electronics industry. For example, they can be used as electroplating resist, plasma etch resist, solder resist, resist for the production of printing plates, resist for chemical milling or resist in the production of integrated circuits. The possible coatings and processing conditions of the coated substrates differ accordingly.

For the production of relief structures, the substrate coated with the photosensitive film is exposed imagewise. The term “imagewise” exposure includes both exposure through a photomask containing a predetermined pattern, exposure by means of a computer controlled laser beam which is moved over the surface of the coated substrate, exposure by means of computer-controlled electron beams, and exposure by means of X-rays or UV rays through a corresponding mask.

Radiation sources, which can be used, are all sources that emit radiation to which the photoacid generator is sensitive. Examples include high pressure mercury lamps, KrF excimer lasers, ArF excimer lasers, electron beams and x-rays sources.

The process described above for the production of relief structures preferably includes, as a further process measure, heating of the photosensitive film between exposure and treatment with the developer. With the aid of this heat treatment, known as “post-exposure bake”, virtually complete reaction of the acid labile groups in the polymer resin with the acid generated by the exposure is achieved. The duration and temperature of this post-exposure bake can vary within broad limits and depend essentially on the functionalities of the polymer resin, the type of acid generator and on the concentration of these two components. The exposed photosensitive film is typically subjected to temperatures of about 50° C. to about 150° C. for a few seconds to a few minutes. The preferred post exposure bake is from about 80° C. to about 130° C. for about 5 seconds to about 300 seconds.

After imagewise exposure and any heat treatment of the material, the exposed areas of the photosensitive film are removed by dissolution in a developer. The choice of the particular developer depends on the type of photosensitive film produced; in particular on the nature of the polymer resin or the photolysis products generated. The developer can include aqueous solutions of bases to which organic solvents or mixtures thereof may have been added. Particularly preferred developers are aqueous alkaline solutions. These include, for example, aqueous solutions of alkali metal silicates, phosphates, hydroxides and carbonates, but in particular of tetra alkylammonium hydroxides, and more preferably tetramethylammonium hydroxide (TMAH). If desired, relatively small amounts of wetting agents and/or organic solvents can also be added to these solutions.

After development, the relief structure may be rinsed with a rinse comprising de-ionized water or comprising de-ionized water containing one or more surfactant and dried by spinning, baking on a hot plate, in an oven, or other suitable means.

Subsequently, the substrate carrying the relief structure is generally subjected to at least one further treatment step, which changes the substrate in areas not covered by the photosensitive film. Typically, this can be implantation of a dopant, deposition of another material on the substrate or an etching of the substrate. This is usually followed by the removal of the photosensitive film from the substrate using a suitable stripping method.

Alternatively, the photosensitive composition of this disclosure may be employed in a multilayer resist process over an undercoat.

In a still further embodiment of this disclosure is a process for the production of relief structures on a substrate by means of a bilayer resist process that comprises:
A) providing a substrate;
B) coating in a first coating step said substrate with a curable underlayer composition;
C) baking and curing said underlayer composition to provide an underlayer film;
D) coating in a second coating step a photosensitive composition over the underlayer film;
E) baking the photosensitive composition in a second baking step to provide a photosensitive film over the underlayer film to produce a bilayer resist stack;
F) exposing the bilayer resist stack to imaging radiation;
G) developing the photosensitive film portion of the bilayer resist stack making a portion of the underlying underlayer film visible;
H) rinsing the bilayer resist stack; and
I) etching the visible underlayer film in an oxidizing plasma to produce a bilayer relief image;
   wherein the photosensitive composition comprises a composition selected from Composition A), Composition B or Composition C), as defined hereinafter in this paragraph and in paragraphs [0090] and [0091]. Composition A) comprises:
a) a polyhedral oligomeric silsesquioxane (POSS) compound selected from compounds of structures (IA)-(IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IA) to (IE) are as follows

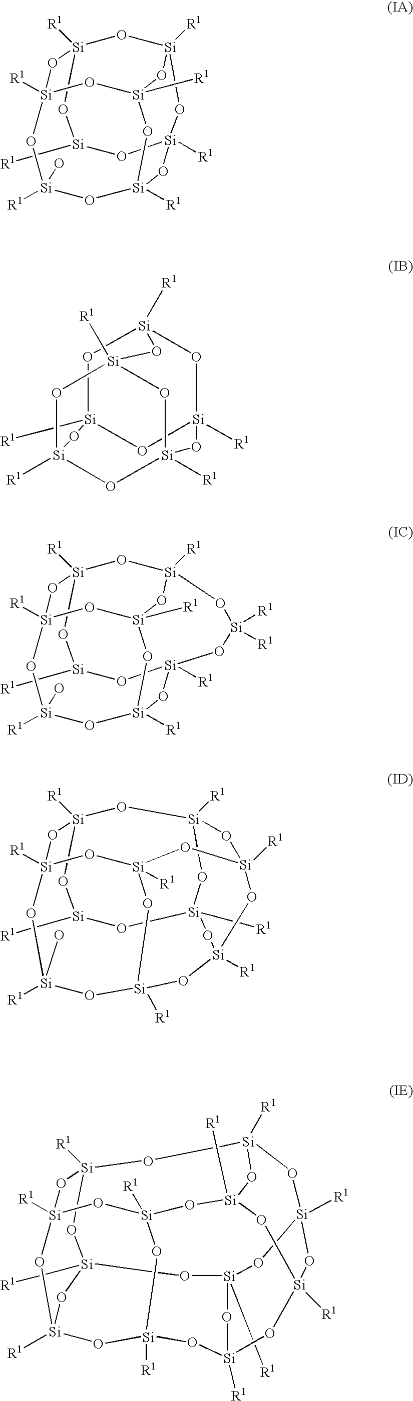

wherein each R¹ is independently a radical of formula (A)

-(J¹)_{c}-(L¹)_{d}-R² (A)

wherein c is an integer from zero to 3;
d is zero or 1;
J¹ is a substituted or unsubstituted C₁-C₁₂ linear, branched or cyclic alkylene group or a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group;
R² is selected from the group consisting of
1) —OR⁵ wherein R⁵ is either a hydrogen atom or a substituted or unsubstituted C₁-C₁₂ linear, branched or cyclic alkyl group; and
2) a cyclic anhydride group of structure (IIA) or a lactone group of structure (IIB):

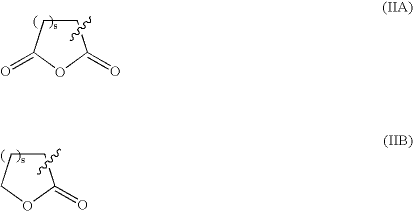

preferably structures (IIA¹) and (IIB¹)

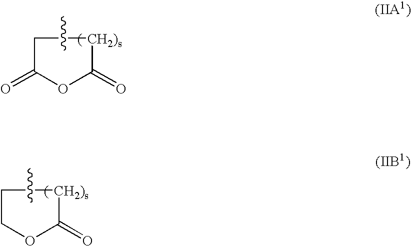

wherein s is an integer from 0 to 3 and structures (IIA), (IIA¹), (IIB) and (IIB¹) may be bonded to L¹ in one or more places.

In this still further embodiment of this disclosure for a process for the production of relief structures on a substrate by means of a bilayer resist process that comprises using Composition B), Composition B) comprises:
a) a polyhedral oligomeric silsesquioxane (POSS) compound selected from compounds of structures (IF) and (IG);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IF) and (IG) are as follows

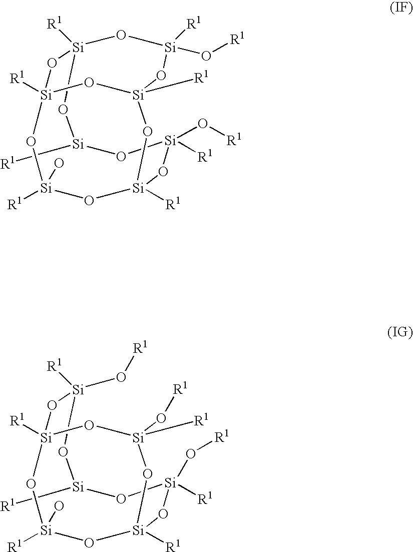

wherein each R¹ is independently a radical of formula (A)

-(J¹)_{c}-(L¹)_{d}-R² (A)

wherein c is an integer from zero to 3;
d is zero or 1;
J¹ is a substituted or unsubstituted C₁-C₁₂ linear, branched or cyclic alkylene group or a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group;
R² is selected from the group consisting of
1) a hydrogen atom;
2) —OR⁵ wherein R⁵ is either a hydrogen atom or a substituted or unsubstituted C₁-C₁₂ linear, branched or cyclic alkyl group; and
3) a cyclic anhydride group of structure (IIA) or a lactone group of structure (IIB):

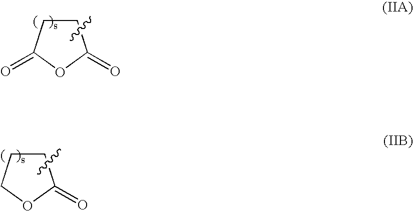

preferably structures (IIA¹) and (IIB¹)

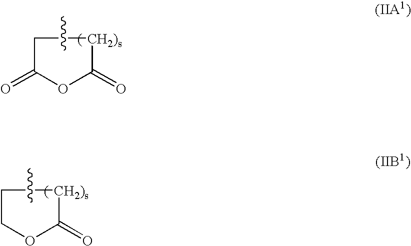

wherein s is an integer from 0 to 3 and structures (IIA), (IIA¹), (IIB) and (IIB¹) may be bonded to L¹ in one or more places;
   each R^{1a} is independently a radical of formula (B)

—(SiR⁶R⁷)-(G)ₑ-R⁸ (B)

wherein R⁶ and R⁷ are each, independently, a substituted or unsubstituted C₁-C₁₂ linear, branched or cyclic alkyl or aryl group;
G is a substituted or unsubstituted C₁-C₁₂ linear, branched, or cyclic alkylene or arylene group;
e is zero or 1;
and R⁸ is selected from the group consisting of
1) a hydrogen atom;
2) —OR⁹ wherein R⁹ is either a hydrogen atom or a substituted or unsubstituted C₁-C₁₂ linear, branched or cyclic alkyl group; and
3) a cyclic anhydride group of structure (IIIA) or a lactone group of structure (IIIB):

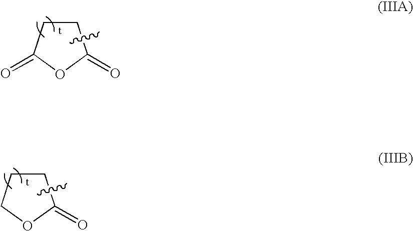

preferably structures (IIIA¹) and (IIIB¹)

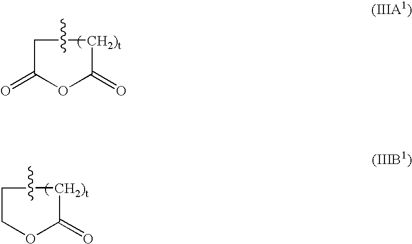

wherein t is an integer from 0 to 3 and structures (IIIA), (IIIA¹), (IIIB) and (IIIB¹) may be bonded to G in one or more places.

In this still further embodiment of this disclosure for a process for the production of relief structures on a substrate by means of a bilayer resist process that comprises using Composition C), Composition C) comprises
a) a polyhedral oligomeric silsesquioxane (POSS) compound selected from compounds of structures (IA), (IB), (ID), and (IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
   wherein Structures (IA), (IB), (ID), and (IE) are as follows

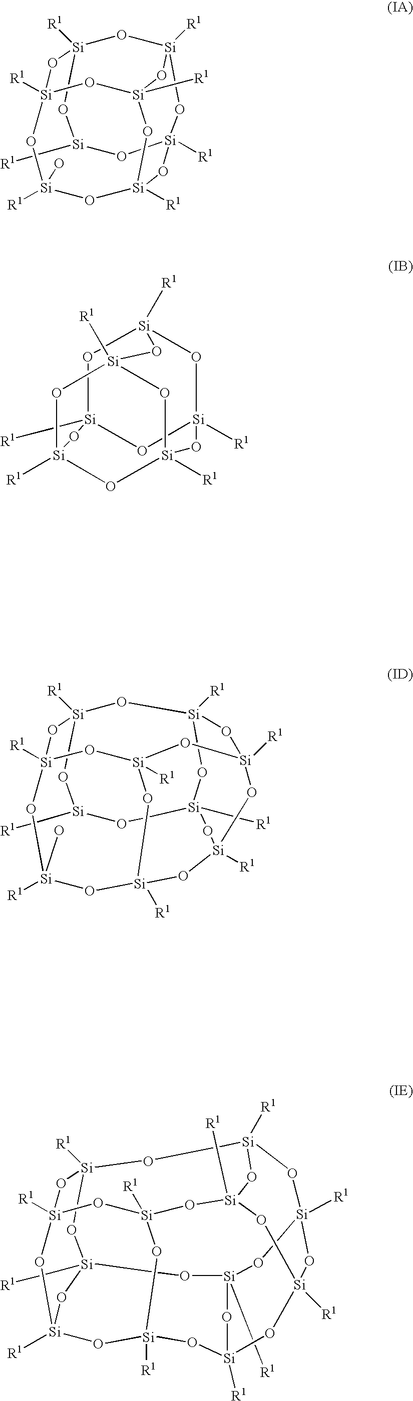

wherein each R¹ is independently a radical of formula (A)

-(J¹)_{c}-(L¹)_{d}-R² (A)

wherein c is an integer from zero to 3;
d is zero;
J¹ is a —(OSiR³R⁴)— group wherein R³ and R⁴ are each, independently, a substituted or unsubstituted C₁-C₁₂ linear, branched or cyclic alkyl or aryl group;
L¹ is a substituted or unsubstituted C₁-C₁₂ linear, branched, or cyclic alkylene or arylene group; and
R² is a hydrogen atom.

The substrate may be, for example, semiconductor materials such as a silicon wafer, compound semiconductor (III-V) or (II-VI) wafer, a ceramic, glass or quartz substrate. Said substrates may also contain films or structures used for electronic circuit fabrication such as organic or inorganic dielectrics, copper or other wiring metals.

In the first coating step, the underlayer composition may be applied uniformly to a suitable substrate by known coating methods. Coating methods include, but are not limited to spray coating, spin coating, offset printing, roller coating, screen printing, extrusion coating, meniscus coating, curtain coating, dip coating, and immersion coating.

After the first coating step, the tacky film of underlayer composition is baked in a first bake step. The baking may take place at one temperature or multiple temperatures in one or more steps. Baking may take place on a hot plate or in various types of ovens known to those skilled in the art. Suitable ovens include ovens with thermal heating, vacuum ovens with thermal heating, and infrared ovens or infrared track modules. Typical times employed for baking will depend on the chosen baking means and the desired time and temperature and will be known to those skilled in the art. A preferred method of baking is on a hot plate. When baking on a hot plate employing a two step process, typical times range from about 0.5 minute to about 5 minutes at temperatures typically between about 80° C. to about 130° C., followed by a cure step for about 0.5 minutes to about 5 minutes typically between about 170° C. to about 250° C. In a one step process, the underlayer film is dried and cured for about 0.5 minutes to about 5 minutes typically between about 170° C. to about 250° C. The underlayer film coated substrate is then allowed to cool. Film thickness of the undercoat will vary depending on the exact application but generally range from about 80 nm to about 1000 nm. Film thicknesses from about 150 nm to about 500 nm are preferred.

Suitable underlayer films have several required characteristics. First, there should be no intermixing between the underlayer film and the photosensitive composition. Generally this is achieved by crosslinking the underlayer film to reduce casting solvent solubility. The crosslinking may be thermally or photochemically induced. Examples of this photochemical and thermal crosslinking may be found in U.S. Pat. No. 6,146,793, U.S. Pat. No. 6,054,248, U.S. Pat. No. 6,323,287, and U.S. Pat. No. 6,165,682 and based upon U.S. Provisional Patent Application No. 60/275,528 hereby incorporated by reference. The preferred method of crosslinking is by heat treatment. Underlayer films are also generally designed to have good substrate plasma etch resistance. Generally, the optical parameters (n, k) of a suitable underlayer film are optimized for the exposure wavelength to minimize reflections.

Coating and imaging of the photosensitive film is substantially the same as described above. The relieve structures formed in the photosensitive film are then transferred into the underlayer film by plasma etching methods utilizing etch gases comprising oxygen. The photosensitive film acts as the etch mask for this operation. The silicon-containing species in the photosensitive film oxidize to silicon dioxide when exposed to an oxygen plasma which increases the etch resistance of the etch mask.

After the oxygen plasma step, the substrate carrying the bilayer relief structure is generally subjected to at least one further treatment step, which changes the substrate in areas not covered by the bilayer coating. Typically this can be implantation of a dopant, deposition of another material on the substrate or an etching of the substrate. This is usually followed by the removal of the photosensitive film and its products and the undercoat.

The present disclosure is further described in detail by the following examples. The examples are presented for illustrative purposes only, and are not intended as a limitation on the scope of the disclosure.

### POSS COMPOUND EXAMPLE 1

The POSS compound octa(dimethylsiloxy)octasilsesquioxane (A-1), was purchased from Hybrid Plastics, Inc. (Hattiesburg, Miss.). Its synthesis can be found in U.S. Pat. No. 5,047,492.

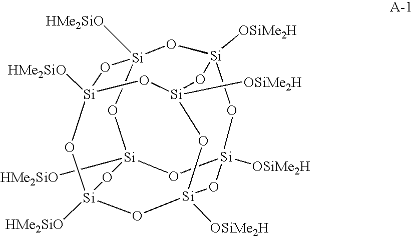

### Formula weight 1018 g/mol; Si content 44.1 wt %

### POSS COMPOUND EXAMPLE 2

POSS Compound Example 2 (A-2) was prepared as follows: In a 100-ml round bottom flask a mixture of octa(dimethylsiloxy)octasilsesquioxane (4.15 g, 4.07 mmol) and allylsuccinic anhydride (4.60 g, 32.5 mmol) was dissolved in toluene (50 ml). To this solution was added Karstedt's catalyst (5 μl of a 2.1-2.4% solution in xylene, available from Gelest, Inc.) at room temperature. The reaction mixture was heated under nitrogen at 60° C. for 12 hours. The reaction was deemed completed when no remaining Si—H absorbance was visible in the IR spectrum. Subsequently the solvent was removed under vacuum and then the crude material was dissolved in PGMEA (31.8 g) to make a 27.17 wt % solution which was used without further purification.

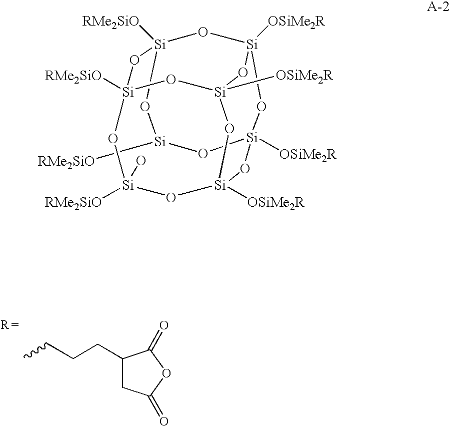

### Formula weight 2139 g/mol; Si content 21.0 wt %

### POSS COMPOUND EXAMPLE 3

POSS Compound Example 3 (A-3) was prepared as follows: In a 100-ml round bottom flask a mixture of octa(dimethylsiloxy)octasilsesquioxane (4.09 g, 3.52 mmol) and 5-norbornene-2,3-dicarboxylic anhydride (5.4 g, 31.4 mmol) was dissolved in toluene (25 ml). To this solution was added Karstedt's catalyst (5 μl of a 2.1-2.4% solution in xylene) at room temperature. The reaction mixture was heated under nitrogen at 100° C. for 12 hours. The reaction was deemed completed when no remaining Si—H absorbance was visible in the IR spectrum. Subsequently the solvent was removed under vacuum and the crude material was used without further purification.

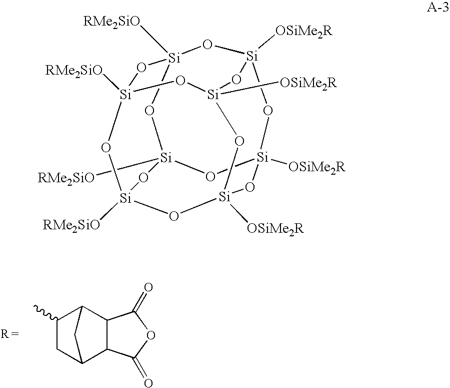

### Formula weight 2331 g/mol; Si content 19.3 wt %

### POSS COMPOUND EXAMPLE 4

The POSS compound hexa(dimethylsiloxy)hexasilsesquioxane (A-4), is prepared according to the method found in U.S. Pat. No. 5,047,492, which is incorporated herein by reference in its entirety.

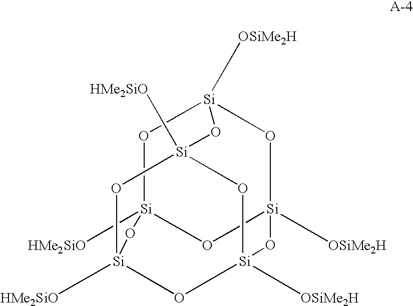

### Formula weight 763 g/mol; Si content 44.1 wt %

### POSS COMPOUND EXAMPLE 5

The POSS compound deca(dimethylsiloxy)decasilsesquioxane (A-5), is prepared according to the method found in U.S. Pat. No. 5,047,492.

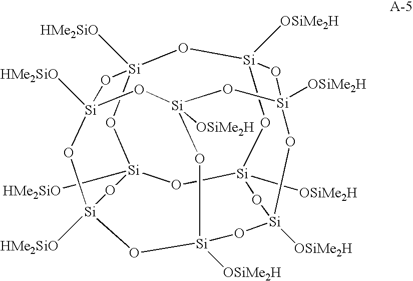

### Formula weight 1272 g/mol; Si content 44.1 wt %

### POSS COMPOUND EXAMPLE 6

The POSS compound octa(hydrido)octasilsesquioxane (A-6), is prepared according to the method found in U.S. Pat. No. 5,106,604, which is incorporated herein by reference in its entirety.

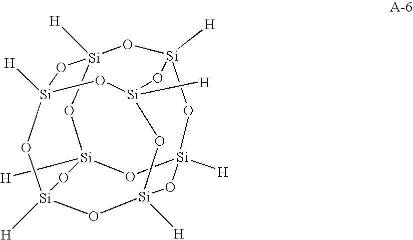

### Formula weight 425 g/mol; Si content 52.9 wt %

### POSS COMPOUND EXAMPLE 7

The POSS compound deca(hydrido)decasilsesquioxane (A-7), is prepared according to the method found in U.S. Pat. No. 5,106,604.

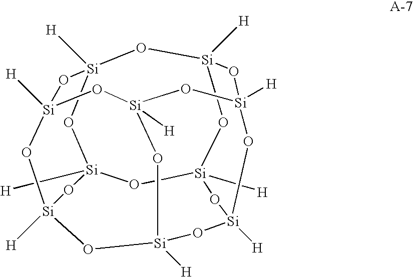

### Formula weight 531 g/mol; Si content 52.9 wt %

### POSS COMPOUND EXAMPLE 8

The POSS compound octa(3-hydroxypropyldimethylsiloxy)octasilsesquioxane (A-8), is commercially available from Mayaterials, Inc. (Ann Arbor, Mich.).

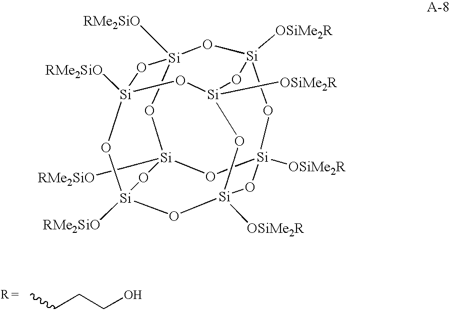

### Formula weight 1483 g/mol; Si content 30.3 wt %

### POSS COMPOUND EXAMPLE 9

The POSS compound A-9, is prepared as follows: Under nitrogen, 3-(dimethylchlorosilyl)propyl succinic anhydride (2.65 g, 11.3 mmol) is added dropwise to a stirring solution of disilanol isobutyl-POSS (5.00 g, 5.61 mmol) (available from Hybrid Plastics, Inc.) and triethylamine (2.30 g, 23 mmol) in THF (25 ml) in a 100 ml round bottom flask cooled in an ice bath. After the addition is complete, the reaction mixture is allowed to warm to room temperature. After stirring overnight at room temperature, the reaction mixture is filtered to remove triethylamine hydrochloride. The solvent is removed from the filtrate under vacuum and the crude material is used without further purification.

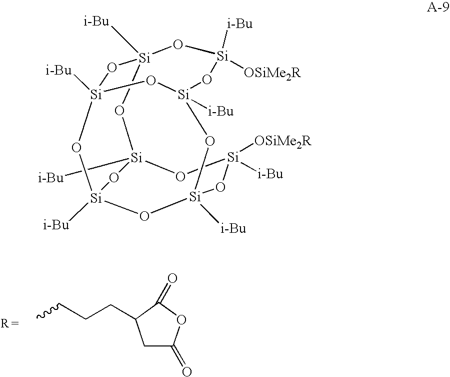

### Formula weight 1288 g/mol; Si content 21.8 wt %

### POSS COMPOUND EXAMPLE 10

The POSS compound A-10, is prepared as follows: Under nitrogen, dimethylchlorosilane (1.50 g, 15.9 mmol) is added dropwise to a stirring solution of trisilanol ethyl-POSS (2.98 g, 5.01 mmol) (available from Hybrid Plastics, Inc.) and triethylamine (2.90 g, 29 mmol) in THF (20 ml) in a 100 ml round bottom flask cooled in an ice bath. After the addition is complete, the reaction mixture is allowed to warm to room temperature. After stirring overnight at room temperature, the reaction mixture is filtered to remove triethylamine hydrochloride. The solvent is removed from the filtrate under vacuum and the crude material is used without further purification.

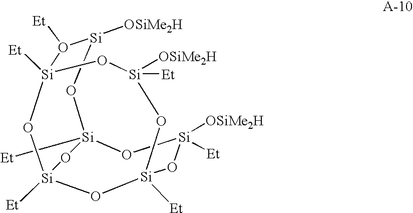

### Formula weight 770 g/mol; Si content 36.5 wt %

### POSS COMPOUND EXAMPLE 11

The POSS compound A-11, is prepared as follows: Under nitrogen, 5-(dimethylchlorosilyl)bicyclo[2.2.1]heptane-2,3-dicarboxylic anhydride (4.11 g, 15.9 mmol) is added dropwise to a stirring solution of trisilanol ethyl-POSS (2.98 g, 5.01 mmol) (available from Hybrid Plastics, Inc.) and triethylamine (2.90 g, 29 mmol) in THF (20 ml) in a 100 ml round bottom flask cooled in an ice bath. After the addition is complete, the reaction mixture is allowed to warm to room temperature. After stirring overnight at room temperature, the reaction mixture is filtered to remove triethylamine hydrochloride. The solvent is removed from the filtrate under vacuum and the crude material is used without further purification.

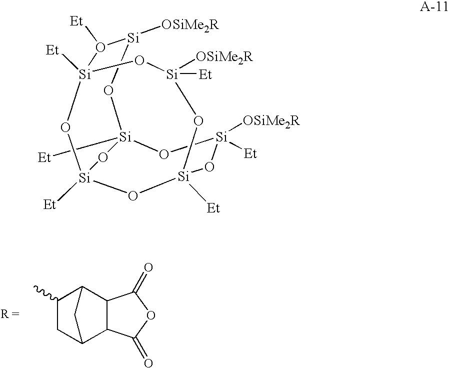

### Formula weight 1262 g/mol; Si content 22.3 wt %

### POSS COMPOUND EXAMPLE 12

POSS Compound Example A-12 is prepared as follows: In a 100-ml round bottom flask a mixture of octa(dimethylsiloxy)octasilsesquioxane (4.09 g, 3.52 mmol) and norbornene lactone (4.72 g, 31.4 mmol) is dissolved in toluene (25 ml). To this solution is added Karstedt's catalyst (5 μl of a 2.1-2.4% solution in xylene) at room temperature. The reaction mixture is heated under nitrogen at 100° C. for 12 hours. The reaction is deemed complete when no remaining Si—H absorbance is visible in the IR spectrum. Subsequently the solvent is removed under vacuum and the crude material is used without further purification.

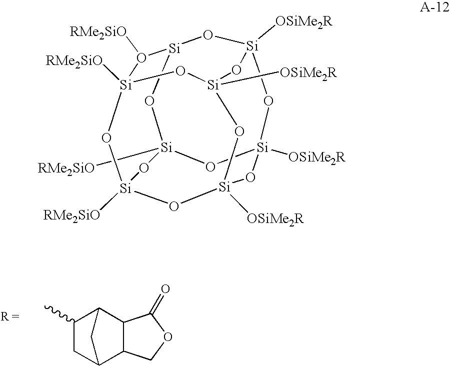

### Formula weight 2219 g/mol; Si content 20.3 wt %

### POLYMER EXAMPLES 1-9

Polymers Examples P-1 to P-9 were prepared by free radical polymerization as described in U.S. Pat. No. 6,165,682. Molecular weight (Mw) and molecular weight distribution data (polydispersivity (PDI)) were measured by Gel Permeation Chromatography (GPC) using a Waters Corp. liquid chromatograph equipped with Millennium GPC V software, refractive index detection, 4 GPC Columns and guard from Phenomenex (Phenogel-10 10-4, 500, 100, & 50A (all 7.8 mm ID×300 mm)) and Phenogel-10 guard 7.8×50 mm), using tetrahydrofuran (THF) eluent and polystyrene calibration. The structure and composition data were determined with ¹H and ¹³C NMR spectrometry using a Bruker Advance 400 MHz nuclear magnetic resonance spectrometer. The results for the polymers are listed in Table 2.

### POLYMER EXAMPLE 10

Polymer Example 10 was prepared by blending polymers P-1 and P-4 on a 50/50 wt/wt ratio.

### POLYMER EXAMPLE 11

Polymer Example 11 was prepared by blending polymers as follows: 10.5 wt % P-1, 24.5 wt % P-5, 27.5 wt % P-6, 14.4 wt % P-7, 14.4 wt % P-8 and 8.7 Wt % P-9.

### POLYMER EXAMPLES 12-16

Polymers P-12 through P-16 were prepared by free radical polymerization similar to the Polymer Example 16 in U.S. Pat. No. 6,916,543. Mw, PDI and structural composition data were determined using the methods described for Polymer Examples 1-9 and the results are shown in Table 2 below.

### POLYMER EXAMPLES 17-19

Polymers P-17, P-18, and P-19 were prepared by free radical polymerization at varying scale but at the same mole ratio as follows: Maleic anhydride (1.565 mol), norbornene (0.955 mol), 3-heptamethylcyclotetrasiloxypropyl norbornene carboxylate (0.581 mol), and t-butyl acrylate (1.036 mol) were dissolved in tetrahydropyran (347.2 g) in an amber glass bottle. V601 initiator (0.208 mol, Wako Chemicals) and additional tetrahydropyran (37.1 g) were added to the monomer solution. This monomer/initiator solution was added over a 6 hour period to tetrahydropyran (82.1 g) in a 5-liter half-jacketed, three-neck flask heated at 70° C. Heating was continued for an additional 6 hours following monomer addition and then the reaction mixture was cooled to room temperature. Mw, PDI and structural composition data were determined using the methods described for Polymer Examples 1-9 and the results are shown in Table 2 below.

TABLE 2
Polymer Composition

| Polymer | | | | |
|---|---|---|---|---|
| Examples | Composition | Mole Ratio | Mw | PDI |
| P-1 | MAH-tBA-ATMS-MA | 31-30-32-7 | 16700 | 2.2 |
| P-2 | MAH-tBA-ATMS-MA | 35-25-31-9 | 15600 | 2.2 |
| P-3 | MAH-tBA-ATMS-MA | 31-27-32-10 | 17300 | 2.5 |
| P-4 | MAH-tBA-ATMS-MA | 32-25-33-10 | 15615 | 2.0 |
| P-5 | MAH-tBA-ATMS-MA | 30-26-34-10 | 15749 | 2.1 |
| P-6 | MAH-tBA-ATMS-MA | 32-30-30-8 | 16019 | 2.0 |
| P-7 | MAH-tBA-ATMS-MA | 29-30-31-10 | 16300 | 2.2 |
| P-8 | MAH-tBA-ATMS-MA | 30-31-33-6 | 15700 | 2.2 |
| P-9 | MAH-tBA-ATMS-MA | 32-31-31-6 | 16450 | 2.2 |
| P-12 | MAH-tBA-ATMS-POSSMA | 37-29-29-5 | 11700 | 2.5 |
| P-13 | MAH-tBA-ATMS-POSSMA | 36-30-29-5 | 10546 | 2.7 |
| P-14 | MAH-tBA-ATMS-POSSMA | 39-28-29-4 | 10404 | 2.0 |
| P-15 | MAH-tBA-ATMS-POSSMA | 38-28-29-5 | 10550 | 2.2 |
| P-16 | MAH-tBA-ATMS-POSSMA | 38-29-28-5 | 11811 | 2.3 |
| P-17 | MAH-tBA-NB-NBD4 | 31-38-20-11 | 13300 | 2.2 |
| P-18 | MAH-tBA-NB-NBD4 | 31-39-20-10 | 10300 | 2.1 |
| P-19 | MAH-tBA-NB-NBD4 | 34-32-23-11 | 10000 | 2.1 |

MAH: maleic anhydride,
tBA: t-butylacrylate,
ATMS: allyltrimethylsilane,
MA: methylacrylate;
POSSMA: 3-[3,5,7,9,11,13,15-heptaethylpentacyclo[9.5.1.1^{(3,9)}.1^{(5,15)}.1^{(7,13)}]octasiloxan-1-yl]propylmethacrylate;
NB: norbornene;
NBD4: 3-heptamethylcyclotetrasiloxypropyl norbornene carboxylate

### FORMULATION EXAMPLES 1-15

In an amber bottle, polymer (either as a solid or as a 38.79 wt % solution in PGMEA), 10-15 wt % PAG solution in PGMEA, 1 wt % DBU solution in PGMEA, a POSS compound and solvent to adjust the solid content of the formulation were mixed. The mixture was then rolled overnight, and the photosensitive composition was filtered through a 0.20 μm Teflon filter. The compositions of the formulations are given in Table 3.

### FORMULATION EXAMPLES 16-24

In an amber bottle, polymer (either as a solid or as a 38.79 wt % solution in PGMEA), 10-15 wt % PAG solution in PGMEA, 1 wt % base solution in PGMEA, a POSS compound and solvent to adjust the solid content of the formulation are mixed. The mixture is then rolled overnight, and the photosensitive composition is filtered through a 0.20 μm Teflon filter. The composition of the formulations is given in Table 3.

### COMPARATIVE FORMULATION EXAMPLES 1-3

In an amber bottle, polymer (either as a solid or as a 38.79 wt % solution in PGMEA), 10-15 wt % PAG solution in PGMEA, 1 wt % DBU solution in PGMEA and solvent to adjust the solid content of the formulation were mixed. The mixture was then rolled overnight, and the photosensitive composition was filtered through a 0.20 μm Teflon filter. The composition of the formulations is given in Table 3.

TABLE 3
Composition of Formulation Examples

| | | | | POSS | |
|---|---|---|---|---|---|
| | Polymer (amount, | PAG | Base | Compound | Solvent |
| Form. Ex. | g) | (amount, g) | (amount, g) | (amount, g) | (amount, g) |
| Comp. 1 | P-10 | PAG-1 | DBU | none | PGMEA |
| | (8.34) | (0.8004) | (0.0618) | | (90.80) |
| 1 | P-10 | PAG-1 | DBU | A-1 | PGMEA |
| | (8.34) | (0.8004) | (0.0618) | (0.37) | (90.80) |
| 2 | P-10 | PAG-1 | DBU | A-1 | PGMEA |
| | (8.34) | (0.8004) | (0.0618) | (0.55) | (90.80) |
| 3 | P-10 | PAG-1 | DBU | A-1 | PGMEA |
| | (8.34) | (0.8004) | (0.0618) | (0.74) | (90.80) |
| 4 | P-2 | PAG-2 | DBU | A-1 | PGMEA |
| | (59.38) | (4.4360) | (0.3310) | (4.10) | (60.03) |
| | | | | | 2-Heptanone |
| | | | | | (651.72) |
| 5 | P-2 | PAG-2 | DBU | A-1 | PGMEA |
| | (1.52) | (0.1138) | (0.0085) | (0.11) | (1.54) |
| | | | | | 2-Heptanone |
| | | | | | (16.711) |
| 6 | P-2 | PAG-2 | DBU | A-1 | PGMEA |
| | (1.52) | (0.1138) | (0.0085) | (0.11) | (1.54) |
| | | | | | 2-Heptanone |
| | | | | | (16.711) |
| Comp. 2 | P-11 | PAG-2 | DBU | none | PGMEA |
| | (7.38) | (0.5800) | (0.0433) | | (92.00) |
| 7 | P-2 | PAG-2 | DBU | A-1 | PGMEA |
| | (9.95) | (0.7870) | (0.0583) | (0.45) | (12.34) |
| | | | | | 2-Heptanone |
| | | | | | (126.41) |
| 8 | P-2 | PAG-2 | DBU | A-1 | PGMEA |
| | (9.73) | (0.7870) | (0.0583) | (0.68) | (12.34) |
| | | | | | 2-Heptanone |
| | | | | | (126.40) |
| 9 | P-2 | PAG-2 | DBU | A-1 | PGMEA |
| | (9.51) | (0.7870) | (0.0583) | (0.90) | (12.34) |
| | | | | | 2-Heptanone |
| | | | | | (126.40) |
| 10 | P-2 | PAG-2 | DBU | A-1 | PGMEA |
| | (8.28) | (0.7870) | (0.0583) | (1.12) | (12.34) |
| | | | | | 2-Heptanone |
| | | | | | (127.41) |
| Comp. 3 | P-3 | PAG-2 | DBU | — | PGMEA |
| | (1.05) | (0.0731) | (0.0055) | | (5.2859) |
| | | | | | 2-Heptanone |
| | | | | | (6.94) |
| 11 | P-3 | PAG-2 | DBU | A-2 | PGMEA |
| | (1.01) | (0.0731) | (0.0055) | (0.03) | (5.3389) |
| | | | | | 2-Heptanone |
| | | | | | (6.94) |
| 12 | P-3 | PAG-2 | DBU | A-2 | PGMEA |
| | (0.98) | (0.0731) | (0.0055) | (0.07) | (5.3919) |
| | | | | | 2-Heptanone |
| | | | | | (6.94) |
| 13 | P-3 | PAG-2 | DBU | A-2 | PGMEA |
| | (0.95) | (0.0731) | (0.0055) | (0.10) | (5.4459) |
| | | | | | 2-Heptanone |
| | | | | | (6.94) |
| 14 | P-3 | PAG-2 | DBU | A-3 | PGMEA |
| | (1.01) | (0.0731) | (0.0055) | (0.03) | (11.736) |
| 15 | P-3 | PAG-2 | DBU | A-3 | PGMEA |
| | (0.98) | (0.0731) | (0.0055) | (0.07) | (11.736) |
| 16 | P-12 | PAG-3 | DBU | A-4 | 2-Heptanone |
| | (1.00) | (0.0731) | (0.0037) | (0.01) | (12.0) |
| 17 | P-13 | PAG-4 | DBU | A-5 | 2-Heptanone |
| | (1.00) | (0.0731) | (0.0073) | (0.07) | (12.0) |
| 18 | P-14 | PAG-5 | THA | A-6 | Cyclohexanone |
| | (1.00) | (0.116) | (0.0022) | (0.02) | (12.0) |
| | | | DBU | | |
| | | | (0.0065) | | |
| 19 | P-15 | PAG-5 | TOA | A-7 | Cyclohexanone |
| | (1.00) | (0.0579) | (0.0022) | (0.10) | (12.0) |
| | | | DBU | | |
| | | | (0.0022) | | |
| 20 | P-16 | PAG-5 | TDDA | A-8 | PGMEA |
| | (1.00) | (0.0731) | (0.0055) | (0.07) | (6.0) |
| | | | | | PGME |
| | | | | | (6.0) |
| 21 | P-18 | PAG-8 | THA | A-9 | PGMEA |
| | (1.00) | (0.0731) | (0.0055) | (0.07) | (6.5) |
| | | | | | 2-Heptanone |
| | | | | | (6.5) |
| 22 | P-19 | PAG-6 | TOA | A-10 | PGMEA |
| | (1.00) | (0.0313) | (0.0055) | (0.07) | (5.5) |
| | | | | | 2-Heptanone |
| | | | | | (5.5) |
| 23 | P-7 | PAG-1 | TP-imid | A-11 | PGMEA |
| | (1.00) | (0.0073) | (0.0055) | (0.07) | (6) |
| | | PAG-3 | | | 2-Heptanone |
| | | (0.0658) | | | (6) |
| 24 | P-8 | PAG-5 | DABCO ™ | A-12 | PGMEA |
| | (0.50) | (0.0366) | (0.0055) | (0.07) | (6) |
| | P-17 | PAG-2 | | | 2-Heptanone |
| | (0.50) | (0.0366) | | | (6) |

Note:
The abbreviations in the table are defined as follows:
PAG-1: tris(t-butylphenyl)sulfonium nonafluorobutanesulfonate;
PAG-2: tolyldiphenylsulfonium perfluoroocanesulfonate;
PAG-3: triphenylsulfonium tris(perfluoromethanesulfonyl)methide;
PAG-4: 4-methylphenyldiphenylsulfonium tris(perfluoroethanesulfonyl);
PAG-5: 4-methylphenyldiphenylsulfonium bis(perfluorobutanesulfonyl)imide;
PAG-6: 2,4,6-trimethylphenyldiphenylsulfonium perfluorobutanesulfonate;
PAG-7: bis(p-toluenesulfonyl)diazomethane;
PAG-8: diphenyliodonium perfluorooctanesulfonate;
DBU: 1,8-diazabicylo[5.4.0]undec-7-ene;
TDDA: tridodecylamine;
THA: trihexylamine;
TOA: trioctylamine;
TP-imid: triphenylimidazole;
DABCO ™: 4-diazabicyclo[2.2.2]octane;
PGMEA: propylene glycol methyl ether acetate;
PGME: propylene glycol monomethyl ether.

### EXAMPLES 1-3 AND COMPARATIVE EXAMPLE 1

### Lithography of Trenches

Silicon oxide wafers (600 nm oxide) were spin coated with a thermally curable underlayer composition and post apply baked (dried and cured) at 205° C. for 90 seconds resulting in 550 nm thick underlayer films. The type of thermally curable underlayer composition was described in U.S. Pat. Appl. No. 2005/0238997.

The photosensitive composition was then coated over the underlayer film, soft baked at 135° C. for 90 seconds resulting in film thicknesses of 265 nm. The coated wafers were then exposed through a binary reticle using an ASM-L 5500/300 (248 nm) scanner with a numerical aperture of 0.63 and sigma of 0.5 using conventional illumination to print 200 nm dense trenches. The exposed wafers were post exposure baked at 125° C. for 90 seconds and subsequently puddle developed with a 2.38% aqueous tetramethylammonium hydroxide (TMAH) solution for 60 seconds and rinsed with deionized water. The wafers were examined top-down with a CD SEM KLA eCD2 for depth of focus (DOF) and exposure latitude (EL) of 200 nm dense trenches at 1:1 pitch. Pattern fidelity was then examined with a Hitachi cross sectional SEM for profile. Results are shown in Table 4.

TABLE 4
Lithographic Results (200 nm dense trenches)

| | | A-1 | | | | |
|---|---|---|---|---|---|---|
| | | loading, | | | | |
| | | wt % of | | | | |
| | Form. | total | Esize | DOF | EL | |
| Ex. # | Ex. # | solids | (mJ/cm²) | (μm) | (%) | Comment |
| Comp. 1 | Comp. 1 | 0 | 18.4 | 0.6 | 18.4 | clean spaces, |
| | | | | | | low LWR |
| 1 | 1 | 4 | 18.4 | 0.7 | 12.4 | clean spaces, |
| | | | | | | low LWR |
| 2 | 2 | 6 | 18.4 | 0.9 | 13.4 | clean spaces, |
| | | | | | | low LWR |
| 3 | 3 | 8 | 18.4 | 1.0 | 15.7 | clean spaces, |
| | | | | | | low LWR |

DOF (depth of focus) and EL (Exposure Latitude) were measured for +/−10% of target CD;
Res (resolution) was the smallest open feature;
Esize (Energy to size) was the exposure energy necessary to print the target feature size to match the mask
LWR (line width roughness) observed on scanning electron micrographs

All trenches were clean and the images exhibited low line width roughness. This demonstrated that the addition of POSS Compound A-1 to the Photosensitive Composition, while increasing its silicon content, did not have a negative impact on its lithographic properties.

### EXAMPLES 4-15 AND COMPARATIVE EXAMPLES 2-3

### Lithography of Line/Space Patterns

Silicon wafers were spin coated with a thermally curable underlayer composition and post apply baked (dried and cured) at 205° C. for 90 seconds resulting in 500 nm thick underlayer films. The thermally curable underlayer used for Examples 4-13 and Comparative Examples 2-3 was TIS193UL 51-50. For Examples 14 and 15 TIS193UL 52-50 was used. Both underlayers are commercially available from Fujifilm Electronic Materials, U.S.A., Inc.

The photosensitive composition was then coated over the underlayer film, soft baked at 130° C. for 60 seconds. The resulting film thickness for Examples 4-13 was 170 nm and for Examples 14 and 15 110 nm. The coated wafers were then exposed with 193 nm radiation through a binary reticle using an ISI Microstepper with a numerical aperture of 0.6 and 0.8/0.6 annular illumination to print 110 nm dense lines. The exposed wafers were post exposure baked at 120° C. for 60 seconds and wafers were subsequently developed with a 2.38% aqueous tetramethylammonium hydroxide(TMAH) solution with a combination of a 5 second stream followed by a 60 second puddle and rinsed with deionized water. The wafers were examined top-down with a CD SEM KLA eCD2 for depth of focus (DOF) and exposure latitude (EL). Pattern fidelity was then examined with a Hitachi cross sectional SEM for profile. Results are shown in Table 5.

For contrast measurements the coated wafers were exposed in open-frame mode with increasing energy starting at an energy dose below the threshold for acid conversion of the PAG to an energy dose where enough PAG is converted to render the silicon containing polymer soluble in an alkali developer. The remaining film thickness in the exposed areas were measured and normalized to 1 for soft baked film thickness and plotted against log₁₀of the energy dose. The negative slope of the line between 0.9 and 0.1 of the normalized film thickness was then reported as contrast. Results are shown in Table 5.

TABLE 5
Lithographic Results (200 nm dense trenches)

| | | POSS | | | | | | |
|---|---|---|---|---|---|---|---|---|
| | | comp. | | | | | | |
| | | (loading, | | | | | | |
| | | wt % of | | | | | | |
| Litho. | Form. | total | Esize | Res | DOF | | | |
| Ex. | Ex. | solids) | (mJ/cm²) | (nm) | (μm) | EL (%) | CONTRAST | Comment |
| 4 | 4 | A-1 | 29.0 | 105.0 | 0.8 | 10.3 | N/A | vertical profiles, very |
| | | (4) | | | | | | clean spaces |
| 5 | 5 | A-1 | 27.5 | 107.5 | 1.1 | 7.4 | N/A | vertical profiles, |
| | | (6) | | | | | | clean spaces, slight |
| | | | | | | | | t-topping |
| 6 | 6 | A-1 | 27.5 | 107.5 | 0.9 | 7.4 | N/A | vertical profiles, |
| | | (6.3) | | | | | | clean spaces, t- |
| | | | | | | | | topping |
| Comp. 2 | Comp. 2 | none | 27.0 | 107.5 | 0.8 | 6.4 | 16.6 | slightly sloped |
| | | | | | | | | profile, rounded tops |
| 7 | 7 | A-1 | 27.0 | 105.0 | 0.9 | 10.1 | 28.9 | vertical lines, |
| | | (4) | | | | | | slightly rounded |
| | | | | | | | | tops |
| 8 | 8 | A-1 | 27.0 | 105.0 | 1.1 | 11.1 | 33.1 | vertical lines, |
| | | (6) | | | | | | slightly rounded |
| | | | | | | | | tops, clean spaces |
| 9 | 9 | A-1 | 27.0 | 105.0 | 1.1 | 11.1 | 34.3 | vertical lines, flat |
| | | (8) | | | | | | tops, clean spaces |
| 10 | 10 | A-1 | 27.0 | 110.0 | 0.5 | 9.3 | 34.1 | vertical lines, flat |
| | | (10.9) | | | | | | tops, clean spaces, |
| | | | | | | | | undercut |
| Comp. 3 | Comp. 3 | none | 34.0 | 105.0 | 1.1 | 5.8 | N/A | rounded lines |
| 11 | 11 | A-2 | 30.0 | 110.0 | 0.5 | 5.8 | N/A | rounded lines |
| | | (1.1) | | | | | | |
| 12 | 12 | A-2 | 30.0 | 105.0 | 0.9 | 10.3 | N/A | rounded lines, |
| | | (2.6) | | | | | | cleaner spaces |
| 13 | 13 | A-2 | 29.0 | 105.0 | 0.9 | 5.8 | N/A | rounded lines, |
| | | (3.8) | | | | | | cleaner spaces, |
| | | | | | | | | improved LWR |
| 14 | 14 | A-3 | 25.0 | 105.0 | 1.2 | — | N/A | vertical profiles, flat |
| | | (0.8) | | | | | | top of the lines, |
| | | | | | | | | clean streets |
| 15 | 15 | A-3 | 24.3 | 105.0 | 1.5 | — | N/A | vertical profiles, flat |
| | | (1.9) | | | | | | top of the lines, |
| | | | | | | | | clean streets, |
| | | | | | | | | improved LWR |

DOF (depth of focus) and EL (Exposure Latitude) were measured for +/−10% of target CD;
Res (resolution) was the smallest open feature;
Esize (Energy to size) was the exposure energy necessary to print the target feature size to match the mask;
CONTRAST measured between 0.9 and 0.1 of normalized film thickness.

The addition of POSS Compound A-1 surprisingly resulted in an increased of contrast in Formulation Examples 7-10. This resulted in more vertical sidewalls of the lines printed.

### EXAMPLE 16-18 AND COMPARATIVE EXAMPLE 4

### Evaluation of O₂/SO₂ Etch Resistance

The photosensitive composition was coated on a silicon wafer, soft baked at 135° C. for 90 seconds resulting in film thicknesses of 240-270 nm. The film was etched in an O₂/SO₂ plasma using a chamber pressure of 10 mTorr, RF Power of 1200 W, bias voltage of 150 V, O₂ flow of 100 sccm and SO₂ flow of 30 sccm. Etch time was 30 seconds. Before and after etch film thickness measurements were performed using a KLA-TENCOR UV1280SE. Bulk etch rates were calculated as follows:

$$\frac{\begin{matrix}FilmThicknessBeforeEtch [ nm ] - \\ FilmThicknessAfterEtch [ nm ]\end{matrix}}{Time [ min ]} = EtchRate [ \frac{nm}{min} ]$$

TABLE 6
Plasma Etch Results

| | | A-1 loading | Total Si Content | Etch Rate |
|---|---|---|---|---|
| Ex. # | Form. Ex. | wt % | (wt %) | (nm/min) |
| Comp. 4 | Comp. 1 | 0 | 7.5 | 128.88 |
| 16 | 1 | 4 | 9.3 | 117.84 |
| 17 | 2 | 6 | 10.1 | 113.82 |
| 18 | 3 | 8 | 11.0 | 109.02 |

The increasing silicon content of Formulation Examples 1-3 resulted in lower plasma etch rates. This will provide better etch selectivity of the Photosensitive Film to the underlayer in the underlayer etch of a bilayer resist system.

### EXAMPLE 19-27

### Evaluation of O₂/SO₂ Etch Resistance

The Photosensitive Compositions from Formulation Examples 16-24 are processed as outlined in the procedure for Examples 16-18. The resulting photosensitive films thus generated exhibit higher O₂/SO₂ etch resistance than photosensitive films generated from Comparative Formulation Example 1.

While the disclosure has been described herein with reference to the specific embodiments thereof, it will be appreciated that changes, modification and variations can be made without departing from the spirit and scope of the inventive concept disclosed herein. Accordingly, it is intended to embrace all such changes, modification and variations that fall with the spirit and scope of the appended claims.

We claim:

1. A photosensitive composition comprising a composition selected from the group consisting of Composition A), Composition B) and Composition C) wherein:
Composition A) comprises a composition of:
a) a polyhedral oligomeric silsesquioxane (POSS) compound selected from the group consisting of structures (IA)-(IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
Composition B) comprises a composition of
a) a polyhedral oligomeric silsesquioxane (POSS) compound selected from the group consisting of structures (IF) and (IG);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
and Composition C) comprises a composition of:
a) a polyhedral oligomeric silsesquioxane (POSS) compound selected from the group consisting of structures (IA), (IB), (ID) and (IE);
b) a developer insoluble silicon-containing polymer capable of exhibiting appreciable solubility in an alkaline developer upon treatment with a strong acid;
c) a photoactive compound capable of generating a strong acid upon exposure to a source of high energy radiation; and
d) a solvent;
wherein Structures (IA) to (IG) are as follows 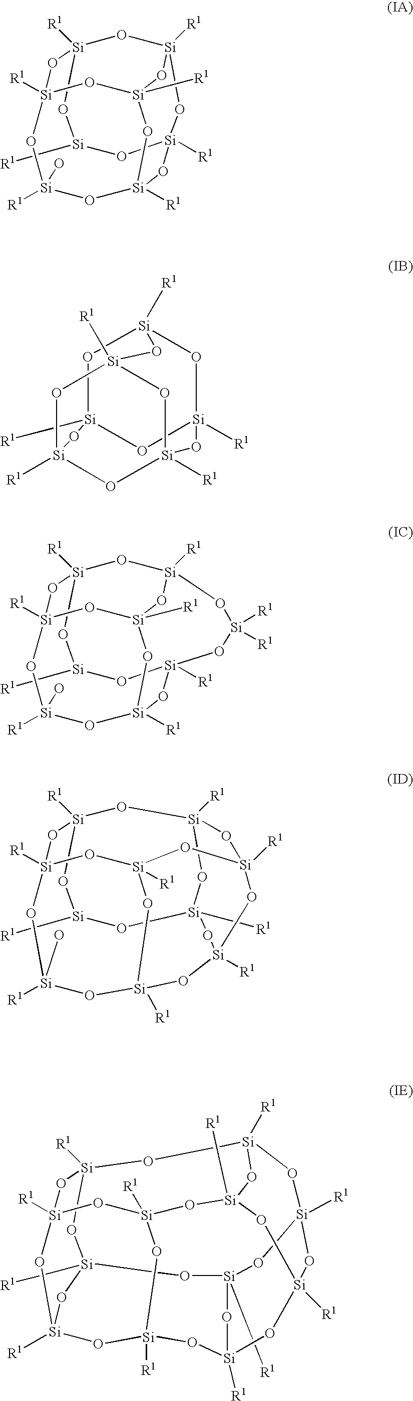 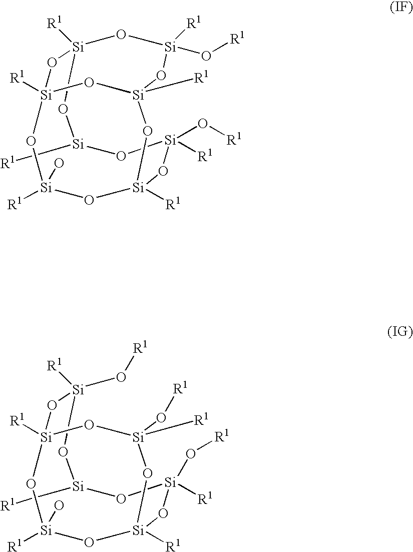
wherein each R¹ is independently a radical of formula (A)
-(J¹)_{c}-(L¹)_{d}-R² (A)
wherein c is an integer from zero to 3;
d is an integer of zero or 1 in Compositions A) and Composition B) and d is zero in Composition C);
in Composition A) and Composition B) J¹ is selected from the group consisting of a substituted or unsubstituted C₁-C₁₂ linear, branched or cyclic alkylene group and a —(OSiR³R⁴)— group wherein R³ and R⁴ are each, independently, selected from the group consisting of a substituted or unsubstituted C₁-C₁₂ linear, branched or cyclic alkyl or aryl group, and in Composition C) J¹ is selected from the group consisting of a —(OSiR³R⁴)— group wherein R³ and R⁴ are each, independently, selected from the group consisting of a substituted or unsubstituted C₁-C₁₂ linear, branched or cyclic alkyl or aryl group;
in Composition A), Composition B) and Composition C) L¹ is selected from the group consisting of a substituted or unsubstituted C₁-C₁₂ linear, branched, or cyclic alkylene or arylene group;
in Composition B) R² is selected from the group consisting of
1) a hydrogen atom;
2) —OR⁵ wherein R⁵ is either a hydrogen atom or a substituted or unsubstituted C₁-C₁₂ linear, branched or cyclic alkyl group; and
3) a cyclic anhydride group of structure (IIA) or a lactone group of structure (IIB); in Composition A) R² is selected from the group consisting of
1) —OR⁵ wherein R⁵ is either a hydrogen atom or a substituted or unsubstituted C₁-C₁₂ linear, branched or cyclic alkyl group; and
2) a cyclic anhydride group of structure (IIA) or a lactone group of structure (IIB); and in Composition C) R² is a hydrogen atom;
wherein in Composition A) and Composition B) Structures (IIA) and (IIB) are 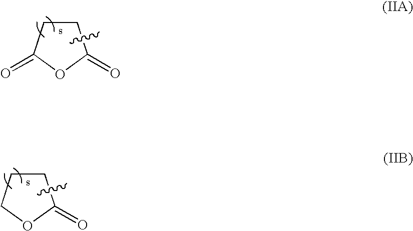
wherein s is an integer from 0 to 3 and structures (IIA) and (IIB) may be bonded to L¹ in one or more places;
each R^{1a} is independently a radical of formula (B)
-(SiR⁶R⁷)-(G)ₑ-R¹ (B)
wherein R⁶ and R⁷ are each, independently, selected from the group consisting of a substituted or unsubstituted C₁-C₁₂ linear, branched or cyclic alkyl or aryl group;
G is selected from the group consisting of a substituted or unsubstituted C₁-C₁₂ linear, branched, or cyclic alkylene or arylene group;
e is an integer of zero or 1;
and R⁸ is selected from the group consisting of
1) a hydrogen atom;
2)-OR⁹ wherein R⁹ is either a hydrogen atom or a substituted or unsubstituted C₁-C₁₂ linear, branched or cyclic alkyl group; and
3) a cyclic anhydride group of structure (IIIA) or a lactone group of structure (IIIB): 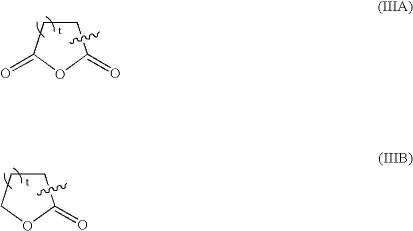
wherein t is an integer from 0 to 3 and structures (IIIA) and (IIIB) may be bonded to G in one or more places;

2. A photosensitive composition according to claim 1 where structures (IIA) and (IIB) are structures (IIA¹) and (IIB¹) 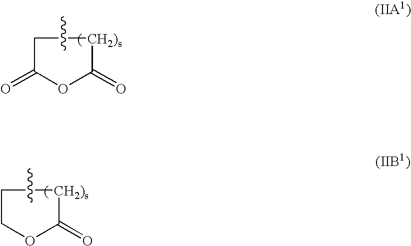
wherein s is an integer from 0 to 3 and structures (IIA¹) and (IIB¹) may be bonded to L¹ in one or more places;
and structures (IIIA) and (IIIB) are structures (IIIA¹) and (IIIB¹) 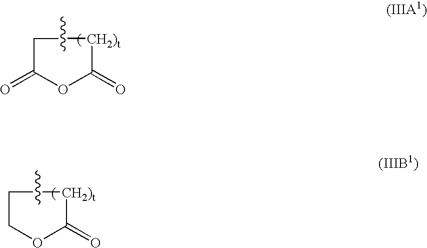
wherein t is an integer from 0 to 3 and structures (IIIA¹) and (IIIB¹) may be bonded to G in one or more places;

3. A photosensitive composition according to claim 1 wherein:
J¹ is selected from the group consisting of methylene, ethylene, propylene, isopropylidene, n-butylene, cyclobutylene, pentylene, iso-pentylene, neo-pentylene, cyclopentylene, hexylene, cyclohexylene, heptylene, cycloheptylene, octylene, decylene, dodecylene, bicyclo[2.2.1]heptylene, tetracyclo[4.4.1^{2,5}.1^{7,10}.0]dodecylene, and when J¹ is a silyloxy group [—(OSiR³R⁴)—], R³ and R⁴ are independently selected from the group consisting of methyl, ethyl, propyl, n-butyl, tert-butyl, cyclobutyl, pentyl, iso-pentyl, neo-pentyl, cyclopentyl, hexyl, cyclohexyl, heptyl, cyclohexylmethyl, cycloheptyl, 2-cyclohexylethyl, octyl, decyl, dodecyl, bicyclo[2.2.1]heptyl, and phenyl;
L¹ is selected from the group consisting of methylene, ethylene, propylene, isopropylidene, n-butylene, cyclobutylene, pentylene, iso-pentylene, neo-pentylene, cyclopentylene, hexylene, cyclohexylene, heptylene, cycloheptylene, octylene, decylene, dodecylene, bicyclo[2.2.1]heptylene, tetracyclo[4.4.1^{2,5}.1^{7,10}.0]dodecylene, phenylene, biphenylene, and naphthalene;
R² in Composition A) is selected from the group consisting of a, hydroxy, methoxy, ethoxy, n-propoxy, isopropoxy, n-butoxy, sec-butoxy, tert-butoxy, cyclobutoxy, pentoxy, iso-pentoxy, neo-pentoxy, cyclopentoxy, hexyloxy, cyclohexyloxy, heptyloxy, cyclohexylmethoxy, cycloheptyloxy, 2-cyclohexylethoxy, octyloxy, decyloxy, dodecyloxy. 2,5-dioxotetrahydrofuran-3-yl and 2-oxotetrahydrofuran-3-yl; and R² in Composition B) is selected from the group consisting of a hydrogen atom, hydroxy, methoxy, ethoxy, n-propoxy, isopropoxy, n-butoxy, sec-butoxy, tert-butoxy, cyclobutoxy, pentoxy, iso-pentoxy, neo-pentoxy, cyclopentoxy, hexyloxy, cyclohexyloxy, heptyloxy, cyclohexylmethoxy, cycloheptyloxy, 2-cyclohexylethoxy, octyloxy, decyloxy, dodecyloxy. 2,5-dioxotetrahydrofuran-3-yl and 2-oxotetrahydrofuran-3-yl; and R² in Composition C) is a hydrogen atom;
G is selected from the group consisting of methylene, ethylene, propylene, isopropylidene, n-butylene, cyclobutylene, pentylene, iso-pentylene, neo-pentylene, cyclopentylene, hexylene, cyclohexylene, heptylene, cycloheptylene, octylene, decylene, dodecylene, bicyclo[2.2.1]heptylene, and tetracyclo[4.4.1^{2,5}.1^{7,10}.0]dodecylene, phenylene, biphenylene, and naphthalene; and is selected from the group consisting of a hydrogen atom, hydroxy, methoxy, ethoxy, n-propoxy, isopropoxy, n-butoxy, sec-butoxy, tert-butoxy, cyclobutoxy, pentoxy, iso-pentoxy, neo-pentoxy, cyclopentoxy, hexyloxy, cyclohexyloxy, heptyloxy, cyclohexylmethoxy, cycloheptyloxy, 2-cyclohexylethoxy, octyloxy, decyloxy, dodecyloxy, 2,5-dioxotetrahydrofuran-3-yl and 2-oxotetrahydrofuran-3-yl.

4. A photosensitive composition according to claim 1 wherein R¹ is selected from the group consisting of a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, and R¹-a to R¹-g: 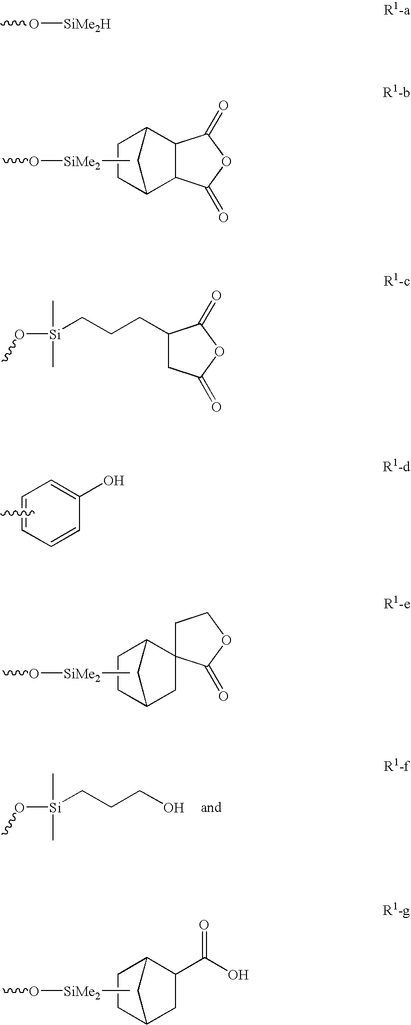
and R^{1a} is selected from the group consisting of Structures R^{1a}-a to R^{1a}-h:

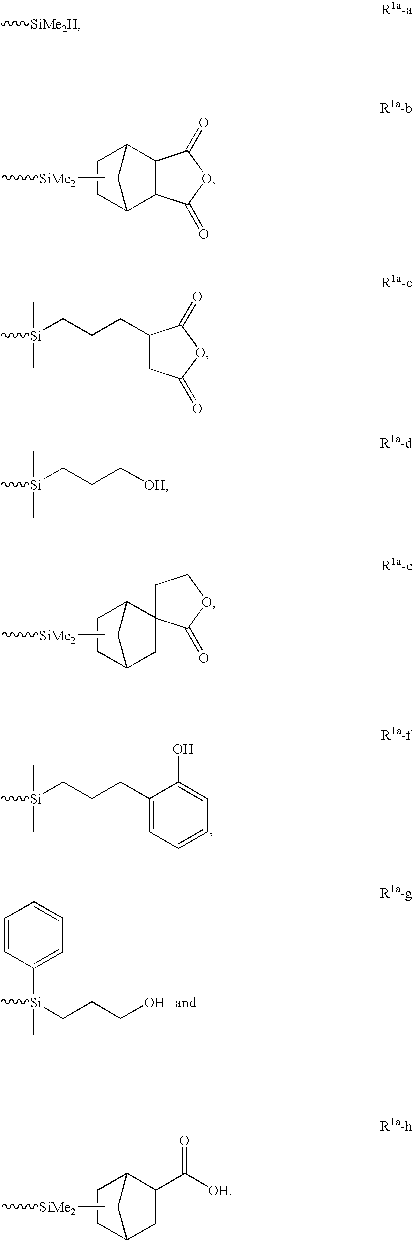

5. A photosensitive composition according to claim 1 wherein in Composition C) in Structure (IA) each R¹ within the Structure is the same and is selected from the group consisting of a hydrogen atom and R¹-a; and in Composition A) each R¹ within the Structure (IA) is the same and is selected from the group consisting of hydroxycyclohexyl, dihydroxycyclohexyl, hydroxybicyclo[2.2.1]heptyl, R¹-b, R¹-c, R¹-d, R¹-e, and R¹-f;
in Composition C) in Structure (IB) each R¹ within the Structure is the same and is selected from the group consisting of a hydrogen atom and R¹-a; and in Composition A) in Structure (IB) each R¹ within the Structure is the same and is selected from the group consisting of hydroxycyclohexyl, dihydroxycyclohexyl, hydroxybicyclo[2.2.1]heptyl, R¹-b, R¹-c, R¹-d, R¹-e and R¹-f;
in Structure (IC) each R¹ within the Structure is the same and is selected from the group consisting of hydroxycyclohexyl, dihydroxycyclohexyl, hydroxybicyclo[2.2.1]heptyl, R¹-b, R¹-c, R¹-d, R¹-e and R¹-f;
in Composition C) in Structure (ID) each R¹ within the Structure is the same and is selected from the group consisting of a hydrogen atom and R¹-a; and in Composition A) in Structure (ID) each R¹ within the Structure is the same and is selected from the group consisting of hydroxycyclohexyl, dihydroxycyclohexyl, hydroxybicyclo[2.2.1]heptyl, R¹-b, R¹-c, R¹-d, R¹-e and R⁴-f;
in Composition C) in Structure (IE) each R¹ within the Structure is the same and is selected from the group consisting of a hydrogen atom and R¹-a; and in Composition A) in Structure (IE) each R¹ within the Structure is the same and is selected from the group consisting of hydroxycyclohexyl, dihydroxycyclohexyl, hydroxybicyclo[2.2.1]heptyl, R¹-b, R¹-c, R¹-d, R¹-e and R¹-f;
in Structure (IF) when each R^{1a} is a R^{1a}-a and each R¹ within the Structure is the same and is selected from the group consisting of a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, R¹-a, R¹-b, R¹-c, R¹-d, R¹-e, R¹-f and R¹-g;
in Structure (IF) when each R^{1a} is R^{1a}-d and each R¹ within the Structure is the same and is selected from the group consisting of is a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, R¹-a, R¹-b, R¹-c, R¹-d, R¹-e, R¹-f and R¹-g;
in Structure (IF) when each R¹ is methyl and each R^{1a} within the Structure is the same and is selected from the group consisting of R^{1a}-b, R^{1a}-c, R^{1a}-e, R^{1a}-f, R^{1a}-g and R^{1a}-h;
in Structure (IF) when each R¹ is ethyl and each R^{1a} within the Structure is the same and is selected from the group consisting of R^{1a}-b, R^{1a}-c, R^{1a}-e, R^{1a}f, R^{1a}-g and R^{1a}-h;
in Structure (IF) when each R¹ is cyclohexyl and each R^{1a} within the Structure is the same and is selected from the group consisting of R^{1a}-b, R^{1a}-c, R^{1a}-e, R^{1a}-f, R^{1a}-g and R^{1a}-h;
in Structure (IG) when each R^{1a} is a R^{1a}-a and each R¹ within the Structure is the same and is selected from the group consisting of a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, R¹-a, R¹-b, R¹-c, R¹-d, R¹-e, R¹-f and R¹-g;
in Structure (IG) when each R^{1a} is R^{1a}-d and each R¹ within the Structure is the same and is selected from the group consisting of a hydrogen atom, methyl, ethyl, n-propyl, isopropyl, n-butyl, isobutyl, sec-butyl, tert-butyl, isooctyl, cyclopentyl, cyclohexyl, hydroxycyclohexyl, dihydroxycyclohexyl, bicyclo[2.2.1]heptyl, hydroxybicyclo[2.2.1]heptyl, carboxybicyclo[2.2.1]heptyl, R¹-a, R¹-b, R¹-c, R¹-d, R¹-e, R¹-f and R¹-g;
in Structure (IG) when each R¹ is methyl and each R^{1a} within the Structure is the same and is selected from the group consisting of R^{1a}-b, R^{1a}-c, R^{1a}-e, R^{1a}-f, R^{1a}-g and R^{1a}-h;
in Structure (IG) when each R¹ is ethyl and each R^{1a} within the Structure is the same and is selected from the group consisting of R^{1a}-b, R^{1a}-c, R^{1a}-e, R^{1a}-f, R^{1a}-g and R^{1a}-h; and
in Structure (IG) when each R¹ is cyclohexyl and each R^{1a} within the Structure is the same and is selected from the group consisting of R^{1a}-b, R^{1a}-c, R^{1a}-e, R^{1a}-f, R^{1a}-g and R^{1a} h;
wherein. R¹-a to R¹-g: is 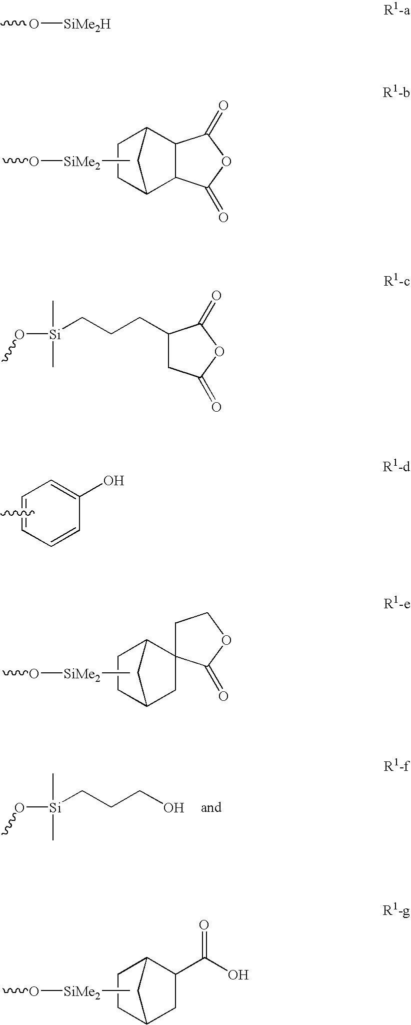
and R^{1a}-a to R^{1a}-h is

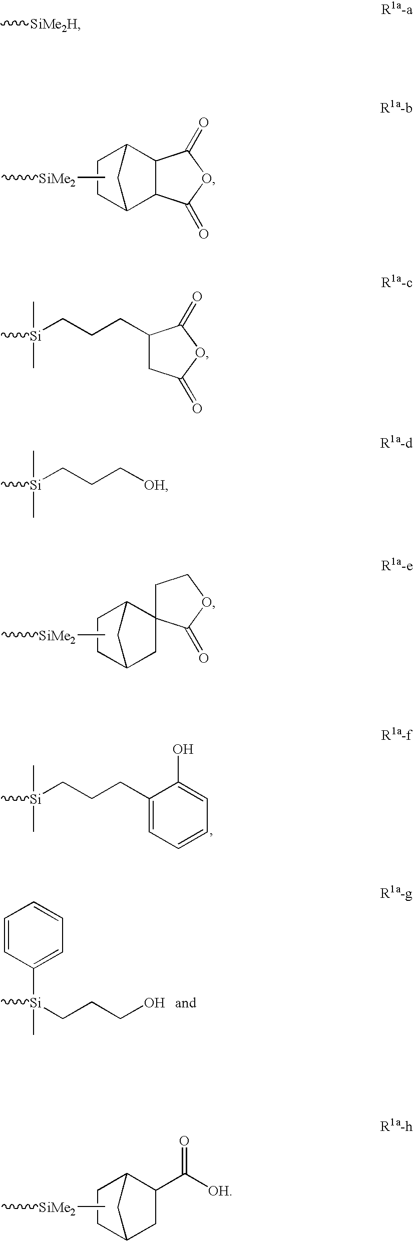

6. A photosensitive composition according to claim 1 wherein the oligomeric silsesquioxane (POSS) compound is selected from the group consisting of:

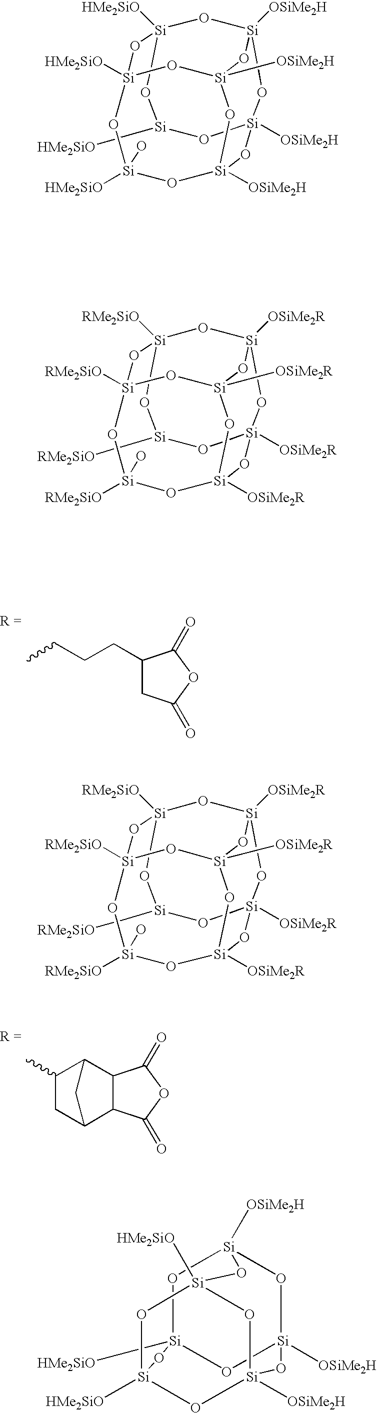

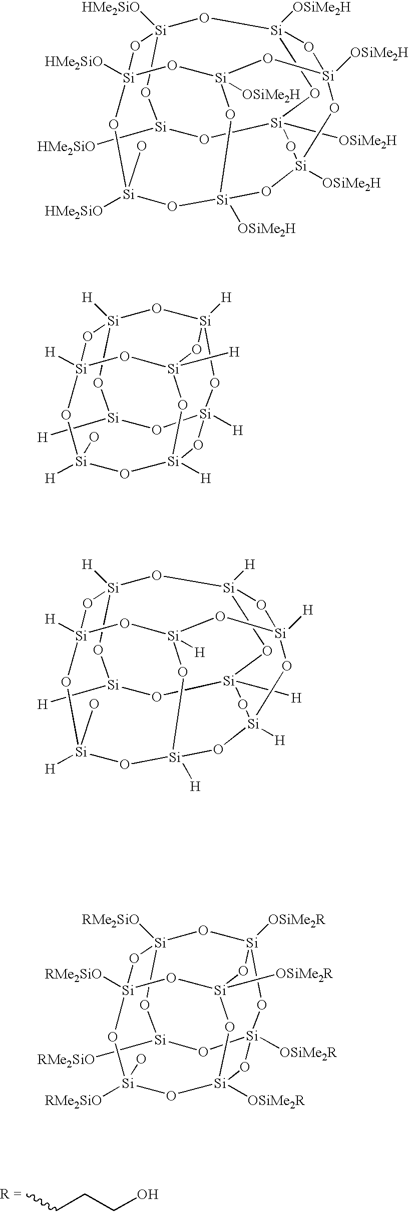

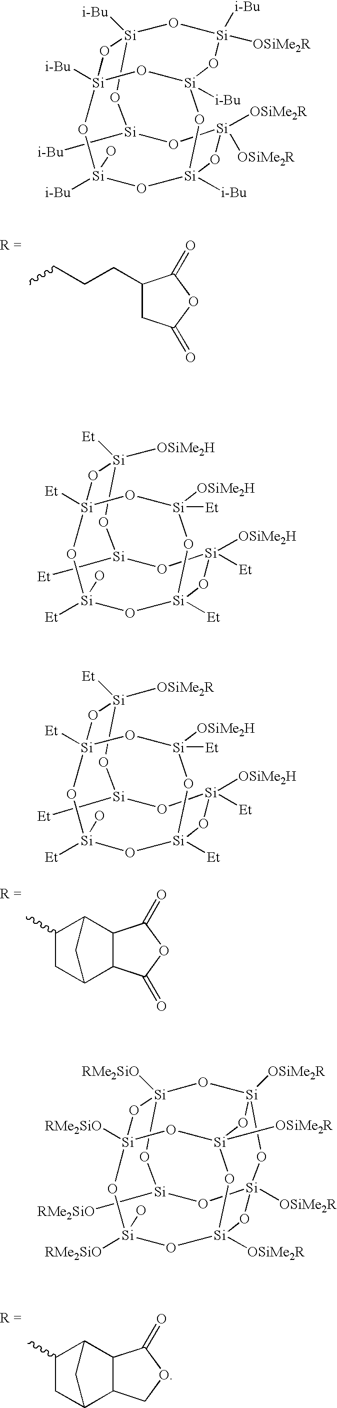

7. A process for production of relief structures on a substrate that comprises:
A) providing a substrate;
B) coating a photosensitive composition on said substrate;
C) baking the photosensitive composition to provide a photosensitive film on the substrate;
D) exposing the photosensitive film to imaging radiation;
E) developing the photosensitive film making a portion of the underlying substrate visible; and
F) rinsing the coated, exposed and developed substrate;
wherein the photosensitive composition comprises a photosensitive composition according to claim 1.

8. A process for production of relief structures on a substrate that comprises:
A) providing a substrate;
B) coating a photosensitive composition on said substrate;
C) baking the photosensitive composition to provide a photosensitive film on the substrate;
D) exposing said photosensitive film to imaging radiation;
E) developing said photosensitive film making a portion of the underlying substrate visible; and
F) rinsing the coated, exposed and developed substrate;
wherein the photosensitive composition comprises a photosensitive composition according to claim 2.

9. A process for production of relief structures on a substrate that comprises:
A) providing a substrate;
B) coating a photosensitive composition on said substrate;
C) baking the photosensitive composition to provide a photosensitive film on the substrate;
D) exposing the photosensitive film to imaging radiation;
E) developing the photosensitive film making a portion of the underlying substrate visible; and
F) rinsing the coated, exposed and developed substrate;
wherein the photosensitive composition comprises a photosensitive composition according to claim 3.

10. A process for production of relief structures on a substrate that comprises:
A) providing a substrate;
B) coating a photosensitive composition on said substrate;
C) baking the photosensitive composition to provide a photosensitive film on the substrate;
D) exposing the photosensitive film to imaging radiation;
E) developing the photosensitive film making a portion of the underlying substrate visible; and
F) rinsing the coated, exposed and developed substrate;
wherein the photosensitive composition comprises a photosensitive composition according to claim 4.

11. A process for production of relief structures on a substrate that comprises:
A) providing a substrate;
B) coating a photosensitive composition on said substrate;
C) baking the photosensitive composition to provide a photosensitive film on the substrate;
D) exposing the photosensitive film to imaging radiation;
E) developing the photosensitive film making a portion of the underlying substrate visible; and
F) rinsing the coated, exposed and developed substrate;
wherein the photosensitive composition comprises a photosensitive composition according to claim 5.

12. A process for production of relief structures on a substrate that comprises:
A) providing a substrate;
B) coating a photosensitive composition on said substrate;
C) baking the photosensitive composition to provide a photosensitive film on the substrate;
D) exposing the photosensitive film to imaging radiation;
E) developing the photosensitive film making a portion of the underlying substrate visible; and
F) rinsing the coated, exposed and developed substrate;
wherein the photosensitive composition comprises a photosensitive composition according to claim 6.

13. A process for the production of relief structures on a substrate by means of a bilayer resist process that comprises:
A) providing a substrate;
B) coating in a first coating step said substrate with a curable underlayer composition;
C) baking and curing said underlayer composition to provide an underlayer film;
D) coating in a second coating step a photosensitive composition over the underlayer film;
E) baking the photosensitive composition in a second baking step to provide a photosensitive film over the underlayer film to produce a bilayer resist stack;
F) exposing the bilayer resist stack to imaging radiation;
G) developing the photosensitive film portion of the bilayer resist stack making a portion of the underlying underlayer film visible;
H) rinsing the bilayer resist stack; and
I) etching the visible underlayer film in an oxidizing plasma to produce a bilayer relief image;
wherein the photosensitive composition comprises a photosensitive composition according to claim 1.

14. A process for the production of relief structures on a substrate by means of a bilayer resist process that comprises:
A) providing a substrate;
B) coating in a first coating step said substrate with a curable underlayer composition;
C) baking and curing said underlayer composition to provide an underlayer film;
D) coating in a second coating step a photosensitive composition over the underlayer film;
E) baking the photosensitive composition in a second baking step to provide a photosensitive film over the underlayer film to produce a bilayer resist stack;
F) exposing the bilayer resist stack to imaging radiation;
G) developing the photosensitive film portion of the bilayer resist stack making a portion of the underlying underlayer film visible;
H) rinsing the bilayer resist stack; and
I) etching the visible underlayer film in an oxidizing plasma to produce a bilayer relief image;
wherein the photosensitive composition comprises a photosensitive composition according to claim 2.

15. A process for the production of relief structures on a substrate by means of a bilayer resist process that comprises:
A) providing a substrate;
B) coating in a first coating step said substrate with a curable underlayer composition;
C) baking and curing said underlayer composition to provide an underlayer film;
D) coating in a second coating step a photosensitive composition over the underlayer film;
E) baking the photosensitive composition in a second baking step to provide a photosensitive film over the underlayer film to produce a bilayer resist stack;
F) exposing the bilayer resist stack to imaging radiation;
G) developing the photosensitive film portion of the bilayer resist stack making a portion of the underlying underlayer film visible;
H) rinsing the bilayer resist stack; and
I) etching the visible underlayer film in an oxidizing plasma to produce a bilayer relief image;
wherein the photosensitive composition comprises a photosensitive composition according to claim 3.

16. A process for the production of relief structures on a substrate by means of a bilayer resist process that comprises:
A) providing a substrate;
B) coating in a first coating step said substrate with a curable underlayer composition;
C) baking and curing said underlayer composition to provide an underlayer film;
D) coating in a second coating step a photosensitive composition over the underlayer film;
E) baking the photosensitive composition in a second baking step to provide a photosensitive film over the underlayer film to produce a bilayer resist stack;
F) exposing the bilayer resist stack to imaging radiation;
G) developing the photosensitive film portion of the bilayer resist stack making a portion of the underlying underlayer film visible;
H) rinsing the bilayer resist stack; and
I) etching the visible underlayer film in an oxidizing plasma to produce a bilayer relief image;
wherein the photosensitive composition comprises a photosensitive composition according to claim 4.

17. A process for the production of relief structures on a substrate by means of a bilayer resist process that comprises:
A) providing a substrate;
B) coating in a first coating step said substrate with a curable underlayer composition;
C) baking and curing said underlayer composition to provide an underlayer film;
D) coating in a second coating step a photosensitive composition over the underlayer film;
E) baking the photosensitive composition in a second baking step to provide a photosensitive film over the underlayer film to produce a bilayer resist stack;
F) exposing the bilayer resist stack to imaging radiation;
G) developing the photosensitive film portion of the bilayer resist stack making a portion of the underlying underlayer film visible;
H) rinsing the bilayer resist stack; and
I) etching the visible underlayer film in an oxidizing plasma to produce a bilayer relief image;
wherein the photosensitive composition comprises a photosensitive composition according to claim 5.

18. A process for the production of relief structures on a substrate by means of a bilayer resist process that comprises:
A) providing a substrate;
B) coating in a first coating step said substrate with a curable underlayer composition;
C) baking and curing said underlayer composition to provide an underlayer film;
D) coating in a second coating step a photosensitive composition over the underlayer film;
E) baking the photosensitive composition in a second baking step to provide a photosensitive film over the underlayer film to produce a bilayer resist stack;
F) exposing the bilayer resist stack to imaging radiation;
G) developing the photosensitive film portion of the bilayer resist stack making a portion of the underlying underlayer film visible;
H) rinsing the bilayer resist stack; and
I) etching the visible underlayer film in an oxidizing plasma to produce a bilayer relief image;
wherein the photosensitive composition comprises a photosensitive composition according to claim 6.

19. A substrate having relief structure formed thereon produced according to the process of claim 7.

20. A substrate having a relief structure formed thereon produced according to the process of claim 13.
